(19) United States
(12) Patent Application Publication
(10) Pub. No.: US 2013/0125959 A1
(43) Pub. Date: May 23, 2013

(54) MOUNT MEMBER, STRUCTURAL OBJECT MOUNT, METHOD FOR INSTALLING THE MOUNT, AND SOLAR PHOTOVOLTAIC SYSTEM USING THE MOUNT

(71) Applicants: Kenichi Sagayama, Osaka-shi (JP); Kenta Nakagawa, Osaka-shi (JP)

(72) Inventors: Kenichi Sagayama, Osaka-shi (JP); Kenta Nakagawa, Osaka-shi (JP)

(73) Assignee: Sharp Kabushiki Kaisha, Osaka-shi, Osaka (JP)

(21) Appl. No.: 13/814,048

(22) PCT Filed: Aug. 2, 2011
(86) PCT No.: PCT/JP2011/067671

§ 371 Date: Feb. 4, 2013

(30) Foreign Application Priority Data
Aug. 4, 2010 (JP) 2010-175676

(51) Int. Cl. H01L 31/042; B23P 11/00

(52) U.S. Cl. CPC H01L 31/0422; B23P 11/00
USPC 136/251; 29/428; 211/41.1

(57) ABSTRACT

A mount member (6) includes a beam (14), two arms (12, 13) for connecting the beam (14) to a strut for supporting the beam (14) and a pair of arm coupling members (26). The pair of arm coupling members (26) couples respective outer ends of the two arms (12, 13) with the beam (14). Each of the arm coupling members (26) is movable between a first state in which the beam (14) and the two arms (12, 13) are overlapped and aligned in a longitudinal direction thereof with the two arms (12, 13) being in line with each other, and a second state in which mutually facing ends of the two arms (12, 13) are spaced apart from the beam (14) relative to the first state.

### TECHNICAL FIELD

The present invention relates to a mount member for supporting a structural object such as a solar cell module, a structural object mount, a method for installing the mount and a solar photovoltaic system using the mount.

### BACKGROUND ART

Examples of known mounts for supporting a structural object such as a solar cell module include those configured in which a plurality of solar cell modules is bridged between a plurality of beams that are arranged in parallel with each other so as to support the solar cell modules.

The mount of this kind includes a number of components such as multiple beams, multiple struts for supporting the beams, multiple arms for coupling the beams with the struts and the like. Therefore, on-site assembling work takes time and labor. For this reason, the beams are in advance assembled at the factory and transported to the site so that the assembled beams are coupled with the struts via the arms on site, thus the mount is completed.

Further, for example, Patent Document 1 discloses a configuration in which a roofing member laminated with a board made of rubber, a reinforcing layer and an adhesive layer is in advance provided with connection terminals and a wiring, and in which the roofing member is secured onto a roof so that a plurality of solar cell modules is arranged in parallel on and connected to the roofing member.

### PRIOR ART REFERENCES

### Patent Documents

[Patent Document 1] JP2002-124695 A

### SUMMARY OF INVENTION

### Problems to be Solved by the Invention

Conventionally, although the on-site assembling work has been simplified by coupling, on site, the beams assembled at the factory with the struts via the arms, coupling work has been difficult. Thus, further simplification of the on-site work has become desirable.

For example, if the arms and the beams are assembled together at the factory and transported to the site, it is possible to further simplify the on-site assembling work. After the step of assembling multiple beams, the assembled beams have a flat structure in a ladder-like shape. Therefore, in case that the flat structures in this state are to be transported to the site, it is possible to stack them for easy transportation. However, once the beams and the arms are assembled, the structure is not flat anymore due to the multiple arms attached to the flat structure. That results in difficulties in transporting, because the structures are bulky and cannot be stacked.

Furthermore, the roofing member disclosed in Patent Document 1 is intended to be laid on a flat surface such as a roof, thus cannot be placed on a mount made up of multiple beams and struts. Therefore, such a roofing member cannot achieve the simplification of the assembling work of the mount.

The present invention has been achieved in view of the above-described conventional problems. It is an object of the present invention to provide a mount member that can be transported as a flat structure and that can considerably simplify the on-site assembling work, a structural object mount, a method for installing the mount and a solar photovoltaic system using the mount.

### Means for Solving the Problems

In order to solve the above-described problems, a mount member according to the present invention is a mount member supporting a structural object, including: a beam, two arms connected to a strut supporting the beam; and a pair of arm coupling members that couples respective outer ends of the two arms with the beam such that the two arms are movable between a first state in which the beam and the two arms are overlapped and aligned in a longitudinal direction thereof with the two arms being in line with each other, and a second state in which mutually facing ends of the two arms are spaced apart from the beam relative to the first state.

In this mount member, when the beam is overlapped with the two arms, the thickness of the mount member is substantially equal to the sum of the thickness of the arm and that of the beam. Since the mount member is not bulky, it is possible to stack a plurality of such mount members. Therefore, it is possible to assemble the arms along with the beams at the factory and to stack and transport a plurality of such mount members. Also, when the mutually facing sides of the two arms are spaced apart from the beam, it is possible to attach the beam to the strut by connecting each of the mutually facing ends of the arms to the strut. Thus, it becomes easy to couple the beam with the strut via the arms.

Also, the mount member having the above-mentioned configuration preferably includes an arm bracket that couples each of the mutually facing ends of the arms with the strut that supports the beam, in which the arm bracket is rotatably provided at each of the mutually facing ends of the arms.

In this case, the mutually facing ends of the arms can be connected to the strut via the respective arm brackets.

Also, in the mount member having the above-mentioned configuration, preferably the arm bracket is rotated toward the beam such that the beam can be fitted inside the arm bracket.

In this way, the beam and the two arms are overlapped. Accordingly, when the beam is fitted inside the arm brackets, the structural object mount is not bulky, thus it is possible to stack and transport a plurality of such structural object mounts.

Also, the mount member having the above-mentioned configuration preferably includes a beam bracket that couples the beam with an upper portion of the strut that supports the beam, in which the beam bracket is rotatably provided in an area between the pair of arm coupling members in the beam.

In this case, the beam can be connected to the upper end of the strut via the beam bracket.

Also, in the mount member having the above-mentioned configuration, preferably the beam bracket is rotated so as to be housed inside the beam.

In this way, when the beam and the two arms are overlapped, and when the beam bracket is housed inside the beam, the structural object mount is not bulky, thus it is possible to stack and transport a plurality of such structural object mounts.

Furthermore, a structural object mount including the mount member according to the above-mentioned means for solving the problems is also within the technical idea of the present invention. That is, a structural object mount according to the present invention includes a strut that supports the beam, in which the mutually facing ends of the arms are connected to the strut in a state in which the mutually facing ends of the arms are spaced apart from the beam.

Thus, a truss structure can be constructed by connecting the mutually facing ends of the arms to the strut in a state in which the mutually facing ends of the arms are spaced apart from the beam.

Also, the structural object mount having the above-mentioned configuration preferably includes a plurality of sets of the beam and the two arms, in which the beams are arranged in parallel as longitudinal beams, and in which a plurality of latitudinal beams is arranged in parallel on the longitudinal beams so as to be orthogonal to the longitudinal beams.

In this way, a plurality of structural objects can be bridged and arranged in parallel on the latitudinal beams.

Also, in the structural object mount having the above-mentioned configuration, the structural object may be a solar cell module.

Furthermore, a mount member according to the present invention may include a plurality of longitudinal beams arranged in parallel, two arms that are provided on each of the longitudinal beams so as to connect the longitudinal beam to a strut for supporting the longitudinal beam, a pair of arm coupling members that is provided on each of the longitudinal beams and that couples respective outer ends of the two arms with the longitudinal beam such that the two arms are movable between a first state in which the longitudinal beam and the two arms are overlapped and aligned in a longitudinal direction thereof with the two arms being in line with each other, and a second state in which mutually facing ends of the two arms are spaced apart from the longitudinal beam relative to the first state, and a plurality of latitudinal beams arranged in parallel on the longitudinal beams so as to be orthogonal to the longitudinal beams.

In this mount member, it is possible that the longitudinal beams are arranged in parallel and that the latitudinal beams are arranged in parallel on the longitudinal beams so as to be orthogonal to the longitudinal beams. It is also possible that the longitudinal beams are overlapped with the respective two arms. For this reason, the mount member is flat, thus a plurality of such mount members can be stacked. It is also possible to assemble the arms along with the longitudinal beams and the latitudinal beams at the factory, so that a plurality of such mount members can be stacked and transported. Furthermore, since the mutually facing ends of the two arms can be spaced apart from the longitudinal beam, it is possible to attach the longitudinal beam to the strut by connecting the mutually facing ends of the arms in this state to the strut. Thus, it becomes easy to couple the longitudinal beam with the strut via the arms.

Also, a method for installing a structural object mount including the mount member according to the above-mentioned means for solving the problems is also within the technical idea of the present invention. That is, a method for installing a structural object mount according to the present invention includes the steps of; erecting the strut; and hanging up and moving the longitudinal beam and the arms above an erected position of the strut, and lowering the longitudinal beam and the arms so as to connect the mutually facing ends of the arms to the strut in a state in which the mutually facing ends of the arms are spaced apart from the beam.

Also, a method for installing a structural object mount according to the present invention is a method for installing the structural object mount including the mount member according to the present invention as described above. Such a method may include the steps of; erecting and arranging the struts corresponding to the longitudinal beams; and hanging up and moving a plurality of sets of the longitudinal beam and the arms coupled with the latitudinal beams above the erected positions of the struts, and lowering the plurality of sets of the longitudinal beam and the arms coupled with the latitudinal beams so as to connect each pair of the mutually facing ends of the respective arms to the corresponding strut in a state in which each pair of the mutually facing ends of the respective arms is spaced apart from the corresponding beam.

In this installation method, the longitudinal beam and the arms, or a plurality of sets thereof coupled with the latitudinal beams are hung up and moved above an erected position of the strut or erected positions of the struts, and are lowered. The mutually facing ends of the two arms are connected to the strut in a state in which the mutually facing ends of the arms are spaced apart from the beam. Thus, it becomes easier to assemble the structural object mount.

Also, a solar photovoltaic system using the structural object mount according to the above-mentioned means for solving the problems is also within the technical idea of the present invention. That is, a solar photovoltaic system according to the present invention is configured in which a plurality of solar cell modules is bridged and supported between the respective latitudinal beams.

This solar photovoltaic system can also obtain the same actions and effects as the structural object mount according to the present invention as described above.

### Effects of the Invention

According to the present invention, when the beam is overlapped with the two arms, the thickness of the mount member is substantially equal to the sum of the thickness of the arm and that of the beam. The mount member is therefore not bulky, thus it is possible to stack a plurality of such mount members. Also, it is possible to assemble the arms along with the beams at the factory and to stack and transport a plurality of such mount members. Furthermore, when the mutually facing sides of the two arms are spaced apart from the beam, it is possible to attach the beam to the strut by connecting the mutually facing sides of the arms to the strut. Thus, it becomes easy to couple the beam with the strut via the arms.

### BRIEF DESCRIPTION OF DRAWINGS

FIG. 1 is a perspective view showing a structural object mount and a solar photovoltaic system that supports a plurality of solar cell modules using the structural object mount according to an embodiment of the present invention.

FIG. 2 is a perspective view showing an example of a solar cell module.

FIG. 3 is a perspective view showing a strut used for the structural object mount of FIG. 1.

FIGS. 4(a) and 4(b) are perspective views showing two arms having different lengths and being used for the structural object mount of FIG. 1.

FIG. 5 is a perspective view showing a longitudinal beam used for the structural object mount of FIG. 1.

FIG. 6 is a perspective view showing a latitudinal beam used for the structural object mount of FIG. 1.

FIG. 7 is a perspective view showing an arm coupling member used for the structural object mount of FIG. 1.

FIG. 8 is a perspective view showing a beam bracket used for the structural object mount of FIG. 1.

FIG. 9 is a perspective view showing arm brackets used for the structural object mount of FIG. 1.

FIG. 10 is a side view showing a truss structure made up of a strut, two arms and a longitudinal beam and the like.

FIG. 11 is an enlarged side view showing a connection portion of the longitudinal beam and the arm bracket of the truss structure of FIG. 10.

FIG. 12 is an enlarged cross-sectional view showing the connection portion of the longitudinal beam and the arm bracket.

FIG. 13 is a perspective view showing an attachment bracket used for connecting and securing the latitudinal beam to the longitudinal beam.

FIG. 14 is a perspective view showing a state in which the attachment bracket of FIG. 13 is attached to the longitudinal beam.

FIG. 15 is a cross-sectional view showing a state in which the latitudinal beam is connected to the longitudinal beam.

FIG. 16 is a perspective view showing a first supporting bracket for connecting and securing solar cell modules to a middle latitudinal beam.

FIG. 17 is an explanation view showing a state in which two first supporting brackets are attached to the latitudinal beam.

FIG. 18 is a perspective view showing a second supporting bracket for connecting and securing solar cell modules to upper or lower latitudinal beam.

FIG. 19 is a cross-sectional view showing a state in which the second supporting bracket is attached to the latitudinal beam.

FIG. 20 is a side view showing a state in which the beam bracket is housed inside the longitudinal beam.

FIG. 21 is a side view showing a state in which each arm is closed to align in parallel with the longitudinal beam and in which each arm bracket is rotated toward the longitudinal beam.

FIG. 22 is a perspective view showing a state in which a plurality of structural object mounts in a flat state is stacked.

FIG. 23 is a cross-sectional view showing a state in which a flange of the arm and a flange of the longitudinal beam are sandwiched by a clip.

FIG. 24 is a perspective view showing a state in which the structural object mount in a flat state is hung up by a crane.

FIG. 25 is a side view showing a state in which each arm is opened obliquely relative to the longitudinal beam and in which the strut is passed toward the longitudinal beam between the arm brackets disposed on the respective ends of the arms.

FIG. 26 is a perspective view showing a securing bracket disposed on a light-receiving surface side of a solar cell module.

FIG. 27 is a partially enlarged perspective view showing a state in which solar cell modules are mounted on the middle latitudinal beam using the first supporting brackets and the securing brackets as viewed from above.

FIG. 28 is a partially enlarged perspective view showing a state in which solar cell modules are mounted on the middle latitudinal beam using the first supporting brackets and the securing brackets as viewed from below.

FIG. 29 is a partially enlarged perspective view showing a state in which each protruding piece of the securing brackets is inserted between frame members of horizontally-adjacent solar cell modules.

FIG. 30(a) is a plan view partially showing a state in which two horizontally-adjacent solar cell modules are mounted on the upper or lower latitudinal beam using the second supporting bracket and the securing bracket, and FIG. 30(b) is a cross-sectional view taken from line B-B of FIG. 30(a).

FIG. 31 is a side view showing a structural object mount according to another embodiment of the present invention.

### MODES FOR CARRYING OUT THE INVENTION

Hereinafter, embodiments of the present invention will be described in detail with reference to the drawings.

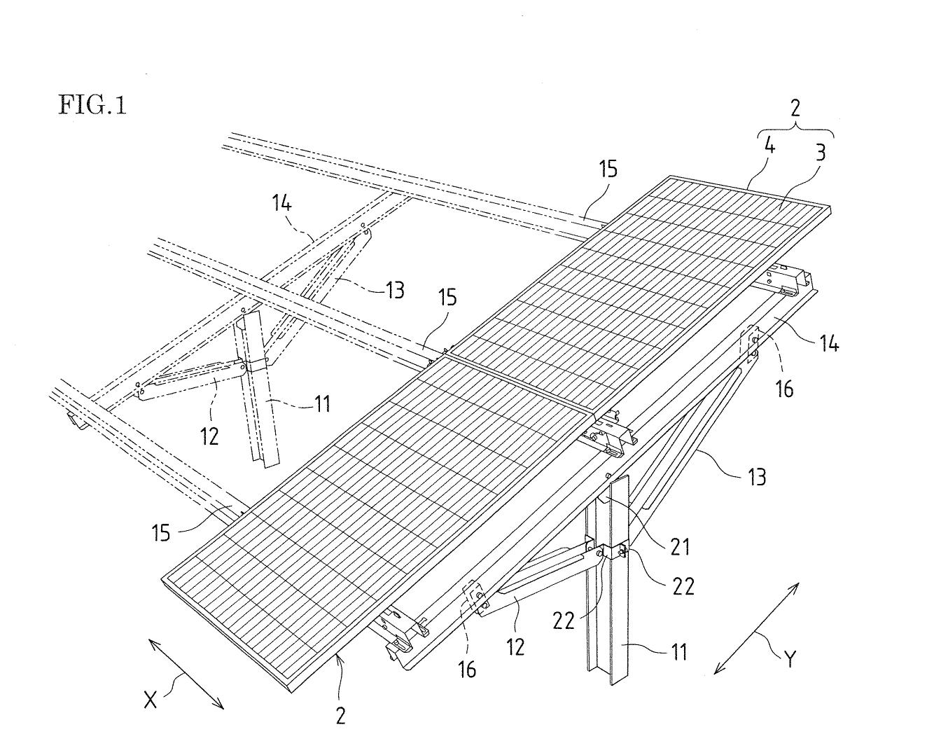

FIG. 1 is a perspective view showing a structural object mount and a solar photovoltaic system that supports a plurality of solar cell modules using the structural object mount according to an embodiment of the present invention.

This solar photovoltaic system, which includes many solar cell modules, is intended to be applied to a power plant. As shown in FIG. 1, a plurality of struts 11 is erected on the ground in a spaced-apart relationship with each other. A plurality of longitudinal beams 14 is connected to respective upper ends of the struts 11 at an angle. Each of two arms 12, 13 is bridged between a body of the strut 11 and the longitudinal beam 14 so as to connect the body of the strut 11 to the longitudinal beam 14. Thus, each longitudinal beam 14 is supported on the corresponding upper end of the strut 11. The plurality of longitudinal beams 14 is disposed parallel to each other in a spaced-apart relationship. Three latitudinal beams 15 are disposed so as to be orthogonal to the longitudinal beams 14, so that the plurality of latitudinal beams 15 is disposed in parallel on the longitudinal beams 14. A plurality of solar cell modules 2 is bridged at an angle between the respective latitudinal beams 15. Both ends of each solar cell module 2 are secured on the respective latitudinal beams 15.

A pair of arm coupling members 16 is provided on the corresponding longitudinal beam 14 so as to protrude downward from the longitudinal beam 14. The arms 12, 13 are connected to respective downward protruding portions of the arm coupling members 16.

Respective ends of the two arms 12, 13 are coupled with the body of the strut 11 between which respective arm brackets 22 are interposed. The body of the strut 11 is supported between the respective arm brackets 22.

A beam bracket 21 is interposed between the upper end of the strut 11 and the longitudinal beam 14 so as to couple the upper end of the strut 11 with the longitudinal beam 14.

A plurality of solar cell modules 2 is mounted so as to be arranged in a horizontal row between the lower latitudinal beam 15 and the middle latitudinal beam 15. Likewise, a plurality of solar cell modules 2 is mounted so as to be arranged in a horizontal row between the middle latitudinal beam 15 and the upper latitudinal beam 15. Therefore, two rows of the plurality of solar cell modules 2 are arranged on the three latitudinal beams 15. Also, four or six solar cell modules 2 are provided between any two horizontally-adjacent longitudinal beams 14.

Note that, in FIG. 1, a direction in which the struts 11 are arranged is referred to as an X direction (a left-right direction) and a direction orthogonal to the X direction is referred to as a Y direction (a front-back direction).

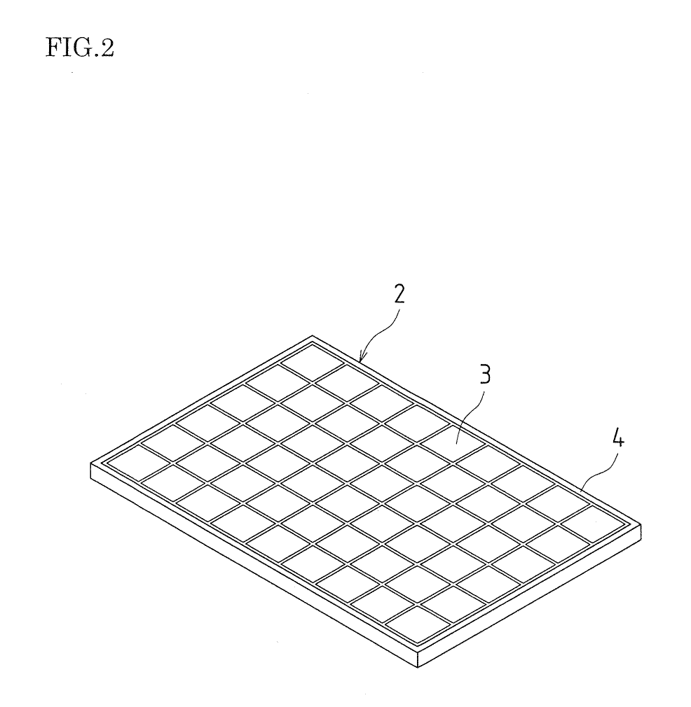

FIG. 2 is a perspective view showing a solar cell module 2. As shown in FIG. 2, the solar cell module 2 includes a solar cell panel 3 converting sunlight into electrical energy and a frame member 4 framing and holding the solar cell panel 3. The frame member 4 is made of an aluminum material and used to enhance the strength of the solar cell module 2 as well as protect the solar cell panel 3.

The structural object mount 5 according to the present embodiment includes the strut 11, the two arms 12, 13, the longitudinal beam 14, the latitudinal beam 15, the arm coupling member 16, the beam bracket 21, the arm bracket 22 and the like, as shown in FIG. 1.

Next, a description will be given of the strut 11, the two arms 12, 13, the longitudinal beam 14, the latitudinal beam 15 and the like that constitute the structural object mount 5.

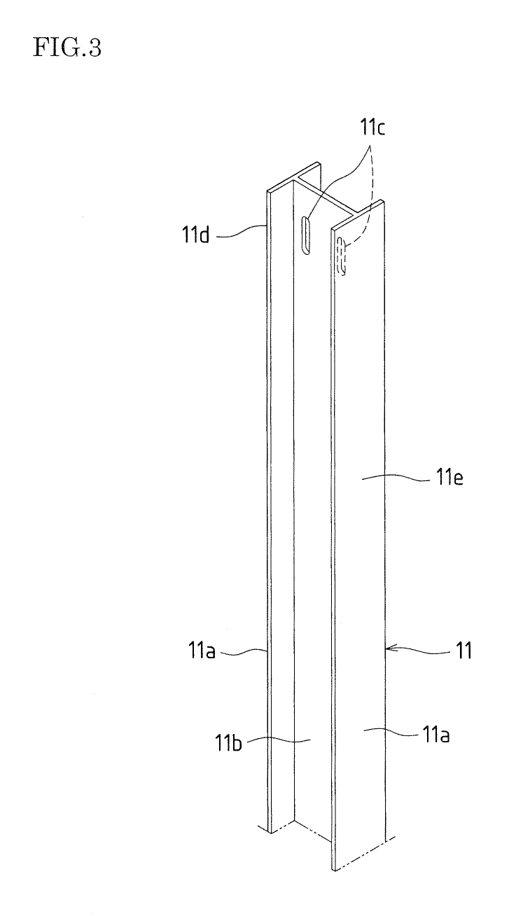

FIG. 3 is a perspective view showing the strut 11. As shown in FIG. 3, the strut 11 is a sectionally H-shaped steel and includes a pair of flanges 11a opposing each other and a web 11b that connects the flanges 11a. At the vicinity of the upper end 11d of the strut 11, two elongated holes 11c are formed in the web 11b so as to extend in the longitudinal direction of the strut 11. Each strut 11 is driven vertically into the ground and erected at substantially the same height.

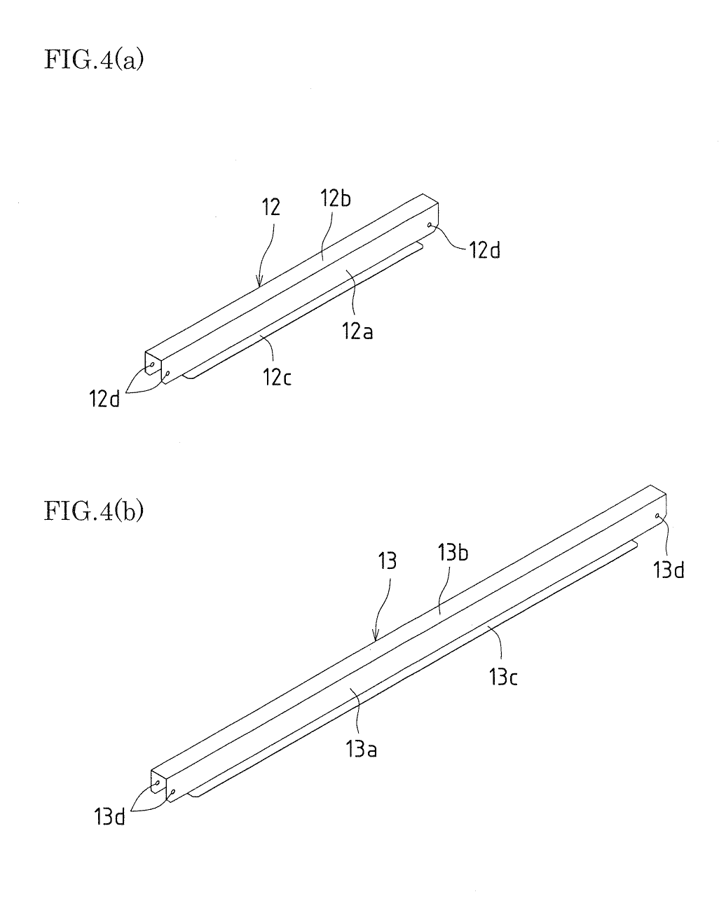

FIGS. 4(a) and 4(b) are perspective views showing the two arms 12, 13, respectively. As shown in FIGS. 4(a) and 4(b), the arms 12, 13 have different lengths. The arm 12, which is connected to a location downward in the inclination of the longitudinal beam 14 in FIG. 1, is short, and the arm 13, which is connected to a location upward in the inclination of the longitudinal beam 14, is long.

The arms 12, 13 include, respectively, main plates 12b, 13b, a pair of side plates 12a, 13a bent on opposite sides of the respective main plates 12b, 13b and flanges 12c, 13c each bent outward at a corresponding edge of the respective side plates 12a, 13a. Each of the arms 12, 13 has a substantially hat-shaped cross-section. Also, the flanges 12c, 13c are removed at respective opposite ends of the arms 12, 13. Bored holes 12d, 13d are formed in the respective side plates 12a, 13a.

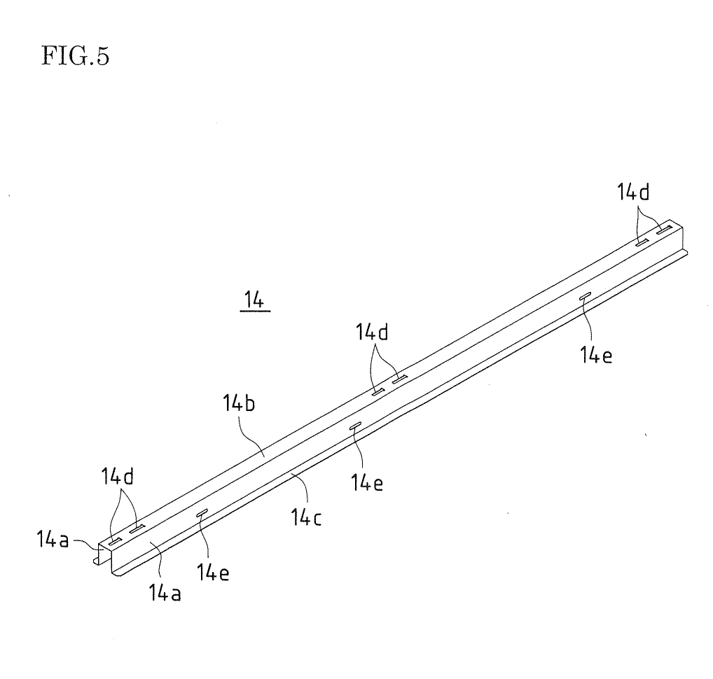

FIG. 5 is a perspective view showing the longitudinal beam 14. As shown in FIG. 5, the longitudinal beam 14 includes a main plate 14b, a pair of side plates 14a bent on opposite sides of the main plate 14b and flanges 14c each bent outward at a corresponding edge of the respective side plates 14a. The longitudinal beam 14 has a substantially hat-shaped cross-section. A pair of T-shaped holes 14d is formed in each vicinity of opposite ends and at the central portion of the main plate 14b of the longitudinal beam 14. In addition, elongated holes 14e are formed at the central portion, an area close to the front end and an area close to the rear end of each side plate 14a, along the longitudinal direction of the longitudinal beam 14.

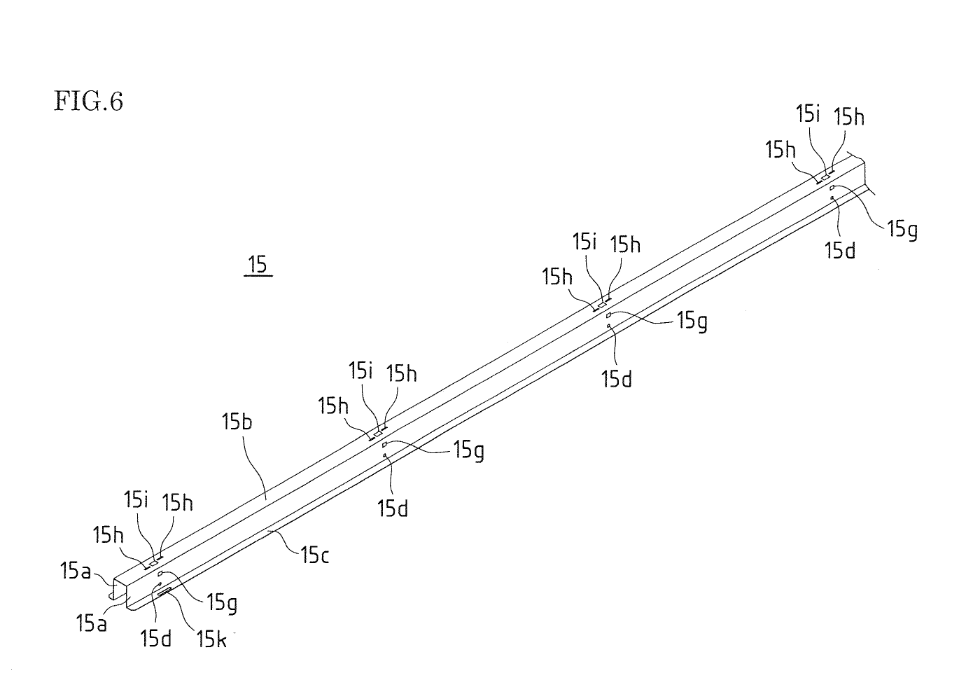

FIG. 6 is a perspective view showing the latitudinal beam 15. As shown in FIG. 6, the latitudinal beam 15 includes a main plate 15b, a pair of side plates 15a bent on opposite sides of the main plate 15b and flanges 15c each bent outward at a corresponding edge of the respective side plates 15a. The latitudinal beam 15 has a substantially hat-shaped cross section. Multiple pairs of a bored hole 15d and a slit 15g are formed at a fixed interval therebetween in the respective side plates 15a of the latitudinal beam 15. Also, multiple sets of two slits 15h and an open hole 15i are formed at the same interval therebetween in the main plate 15b of the latitudinal beam 15. Further, elongated holes 15k are formed, spaced apart from each other by an interval at which each longitudinal beam 14 is placed, in the respective flanges 15c of the latitudinal beam 15.

Since the latitudinal beam 15 is very long in the X direction, it is difficult to form the latitudinal beam 15 as a single member. Accordingly, the latitudinal beam 15 is formed by connecting a plurality of beam members together.

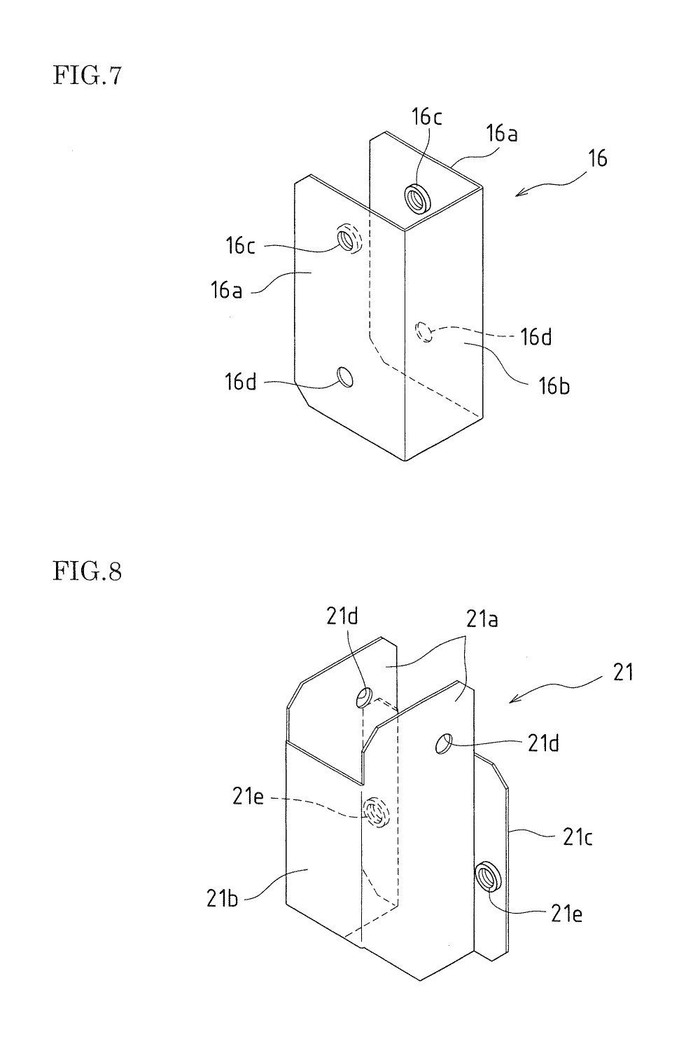

FIG. 7 is a perspective view of the arm coupling member 16. As shown in FIG. 7, the arm coupling member 16 includes a main plate 16b and a pair of side plates 16a bent on opposite sides of the main plate 16b. The arm coupling member 16 has a substantially C-shaped cross-section. A screw hole 16c and a bored hole 16d are formed in each side plate 16a of the arm coupling member 16. Since the outer separation width of the pair of side plates 16a is set to be the same as or slightly narrower than the inner separation width of the pair of side plates 14a of the longitudinal beam 14, it is possible to insert the pair of side plates 16a of the arm coupling member 16 within the pair of side plates 14a of the longitudinal beam 14.

FIG. 8 is a perspective view showing the beam bracket 21. As shown in FIG. 8, the beam bracket 21 includes a main plate 21b, a pair of side plates 21a bent on opposite sides of the main plate 21b and flanges 21c each bent outward at a corresponding edge of the respective side plates 21a. The beam bracket 21 has a substantially hat-shaped cross-section. Also, the flanges 21c are removed at one end of the beam bracket 21. A bored hole 21d is formed in each of the side plates 21a and a screw hole 21e is formed in each of the flanges 21c. Since the outer separation width of the pair of side plates 21a is set to be the same as or slightly narrower than the inner separation width of the pair of side plates 14a of the longitudinal beam 14, it is possible to insert the pair of side plates 21a of the beam bracket 21 within the pair of side plates 14a of the longitudinal beam 14.

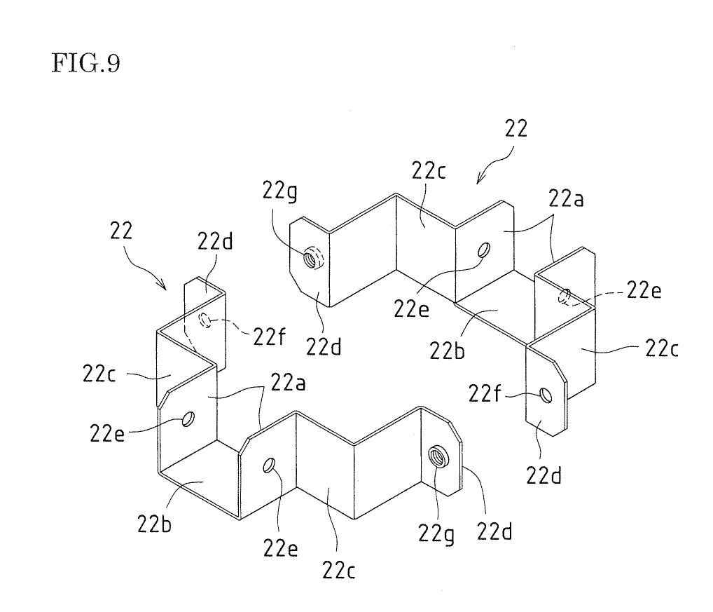

FIG. 9 is a perspective view showing the arm brackets 22. As shown in FIG. 9, the arm bracket 22 includes a main plate 22b, a pair of side plates 22a bent on opposite ends of the main plate 22b, a pair of L-shaped portions 22c each bent at a corresponding edge of the respective side plates 22a and further bent so as to form a L-shape, and a pair of connecting plates 22d each bent at a corresponding edge of the respective L-shaped portions 22c. A bored hole 22e is formed in each of the side plates 22a. A bored hole 22f and a screw hole 22g are formed in the respective connecting plates 22d. Since the outer separation width of the pair of side plates 22a is set to be the same as or slightly narrower than the inner separation width of the pair of side plates 12a or 13a of the arm 12 or 13, it is possible to insert the pair of side plates 22a of the arm bracket 22 within the pair of side plates 12a or 13a of the arm 12 or 13. Also, the inside of the pair of L-shaped portions 22c of the arm bracket 22 has a size and shape with which the flanges 11a of the strut 11 are fitted.

Here, all the arms 12, 13, the longitudinal beam 14 and the latitudinal beam 15 each have a hat-shaped cross-section configured by a main plate, a pair of side plates bent on opposite sides of the main plate and flanges each bent outward at a corresponding edge of the respective side plates. Also, all the hat-shaped cross-sections have the same size. Furthermore, all of them are formed by cutting a coated steel plate having the same thickness or by making holes through the coated steel plate, and further by bending the coated steel plate. Accordingly, material and processing apparatuses can be shared, thus achieving a significant cost reduction.

Next, a description will be given of a truss structure made up of the strut 11, two arms 12, 13, the longitudinal beam 14 and the like.

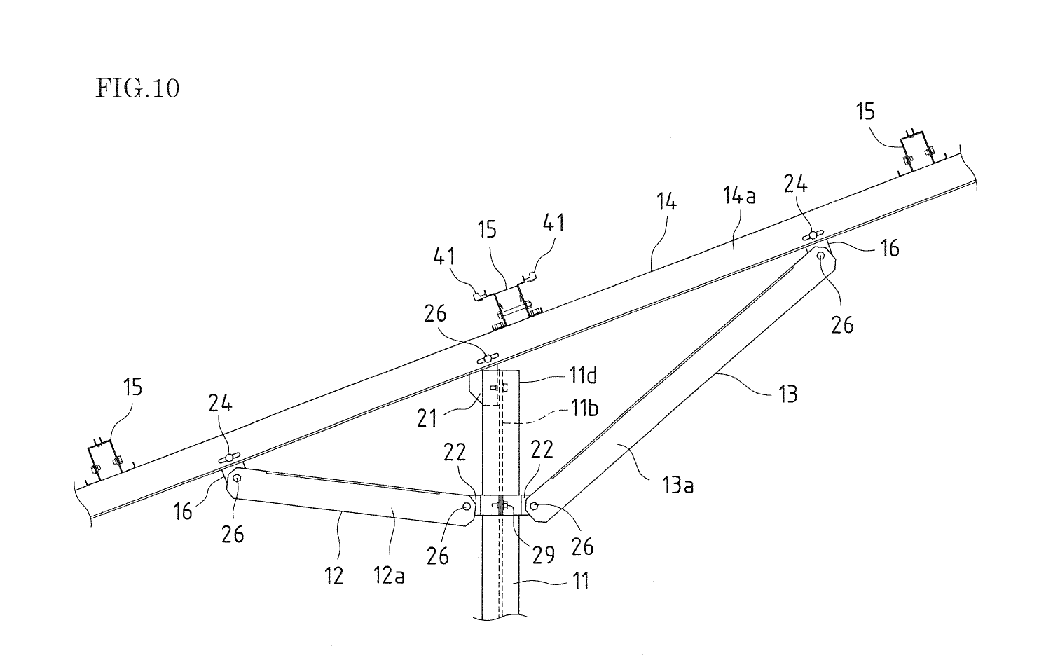

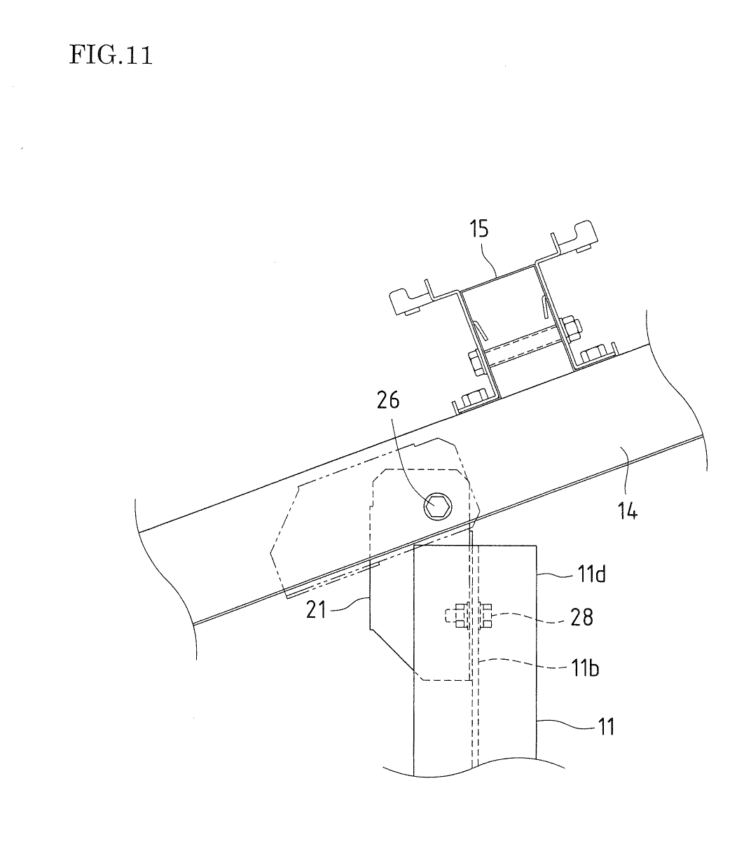

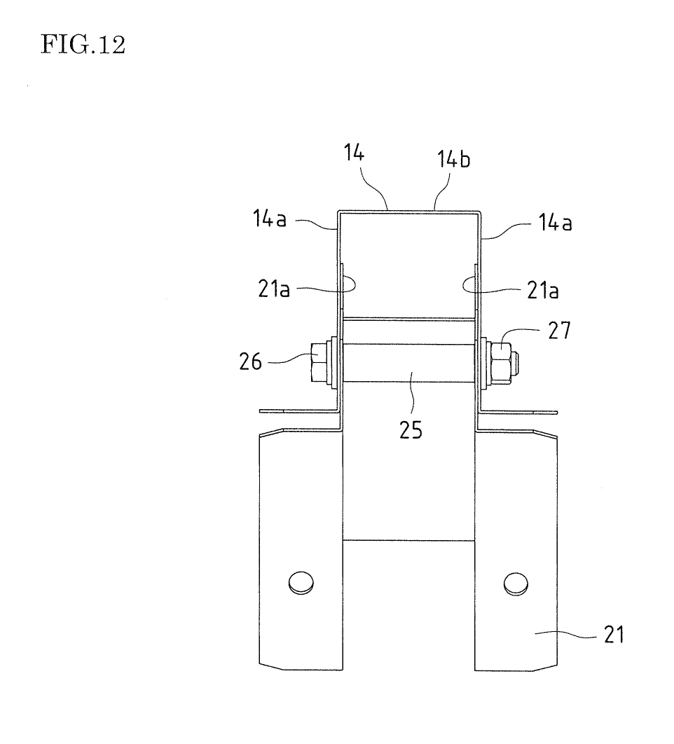

FIG. 10 is a side view showing the truss structure. Also, FIGS. 11 and 12 are respectively a side view and a cross-sectional view each showing an enlarged connection portion of the longitudinal beam and the arm bracket.

As shown in FIG. 10, the truss structure is formed by coupling the central portion of the longitudinal beam 14 to the upper end 11d of the strut 11 via the beam bracket 21, connecting one end of the arm 12 to the area close to the front end of the longitudinal beam 14 via the arm coupling member 16, connecting one end of the arm 13 to the area close to the rear end of the longitudinal beam 14 via the arm coupling member 16 and connecting the other end of each arm 12, 13 to the body 11e of the strut 11 via each of two arm brackets 22.

As shown in FIGS. 11 and 12, at the central portion of the longitudinal beam 14, the side plates 21a of the beam bracket 21 are inserted into and overlapped with the inside of the side plates 14a of the longitudinal beam 14. A pipe 25 is inserted between the side plates 21a of the beam bracket 21. Positions of the pipe 25, the bored holes 21d of the side plates 21a of the beam bracket 21 and the elongated holes 14e of the side plates 14a of the longitudinal beam 14 are aligned. A bolt 26 is passed through the pipe 25, the bored holes 21d of the side plates 21a of the beam bracket 21, the elongated holes 14e of the side plates 14a of the longitudinal beam 14 and a washer. A nut 27 is screwed and fastened to one end of the bolt 26, thereby the beam bracket 21 is connected to the central portion of the longitudinal beam 14.

The beam bracket 21 is supported by the single bolt 26 relative to the side plates 14a of the longitudinal beam 14, thus the beam bracket 21 is rotatable about the bolt 26.

Also, in each area close to the front end and the rear end of the longitudinal beam 14, an upper portion of the side plates 16a of the corresponding arm coupling member 16 is inserted into and overlapped with the inside of the side plates 14a of the longitudinal beam 14. A bolt 24 is screwed and tightened to the screw holes 16c of the side plates 16a of the arm coupling members 16 through the respective elongated holes 14e of the side plates 14a of the longitudinal beam 14. Thereby the arm coupling members 16 are connected.

Here, in the arm coupling members 16 connected to the respective areas close to the front end and the rear end of the longitudinal beam 14, respective lower portions of the arm coupling members 16 protrude downward from the longitudinal beam 14.

Similarly to FIG. 12, at one end of the arm 12 that is coupled with the area close to the front end of the longitudinal beam 14, the downward protruding portion of the side plates 16a of the arm coupling member 16 is inserted into and overlapped with the inside of the side plates 12a of the arm 12. A pipe 25 is inserted between the side plates 16a of the arm coupling member 16. A bolt 26 is passed through the pipe 25, the bored holes 16d of the side plates 16a of the arm coupling member 16, the bored holes 12d of the side plates 12a of the arm 12 and a washer. A nut 27 is screwed and fastened to one end of the bolt 26, thereby the above end of the arm 12 is connected to the downward protruding portion of the arm coupling member 16.

Furthermore, at one end of the arm 13 that is coupled with the area close to the rear end of the longitudinal beam 14, the above end of the arm 13 is connected to the downward protruding portion of the arm coupling member 16 using the pipe 25, the bolt 26 and the nut 27.

Each arm 12, 13 is supported by the corresponding bolt 26 relative to the downward protruding portion of the corresponding arm coupling member 16, thus the arms 12, 13 are rotatable about the respective bolts 26.

Similarly to FIG. 12, at the other end of the arm 12 that is coupled with the body 11e of the strut 11, the side plates 22a of the arm bracket 22 is inserted into and overlapped with the inside of the side plates 12a of the arm 12. A pipe 25 is inserted between the side plates 22a of the arm bracket 22. A bolt 26 is passed through the pipe 25, the bored holes 22e of the side plates 22a of the arm bracket 22, the bored holes 12d of the side plates 12a of the arm 12 and a washer. A nut 27 is screwed and fastened to one end of the bolt 26, thereby the other end of the arm 12 is connected to the arm bracket 22.

Furthermore, at the other end of the arm 13 that is coupled with the body 11e of the strut 11, the other end of the arm 13 is connected to the arm bracket 22 using the pipe 25, the bolt 26 and the nut 27.

Each arm bracket 22 is supported by the corresponding bolt 26 relative to the side plates of each arm 12, 13, thus the arm brackets 22 are rotatable about the respective bolts 26.

Therefore, the connection between the longitudinal beam 14 and the beam bracket 21, the connection between each downward protruding portion of the arm coupling members 16 and the corresponding end of the respective arms 12, 13, and the connection between each of the other ends of the arms 12, 13 with the corresponding arm bracket 22, are all carried out using the pipe 25, the bolt 26 and the nut 27.

Meanwhile, as shown in FIGS. 10 and 11, the flanges 21c of the beam bracket 21 of the longitudinal beam 14 are overlapped with the web lib of the strut 11, with the central portion of the longitudinal beam 14 being mounted on the upper end 11d of the strut 11. The screw holes 21e of the flanges 21c of the beam bracket 21 are each overlapped with the corresponding elongated hole 11c of the web lib. Two bolt 28 are screwed and tightened to the respective screw holes 21e of the flanges 21c of the beam bracket 21 through the respective elongated holes 11c of the web lib. Thus, the beam bracket 21 is secured on the upper end 11d of the strut 11, and the central portion of the longitudinal beam 14 is coupled with the upper end 11d of the strut 11 via the beam bracket 21.

Also, the arm brackets 22 of the arms 12, 13 face each other, with the strut 11 being interposed therebetween. The flanges 11a of the strut 11 are fitted with the inside of the respective L-shaped portions 22c of the both arm brackets 22, thus the connecting plates 22d of one arm bracket 22 are overlapped with the connecting plates 22d of the other arm bracket 22. In this case, since the bored hole 22f and the screw hole 22g of one pair of connecting plates 22d face respectively the screw 22g and the bored hole 22f of the other pair of connecting plates 22d, it is possible to connect the arm brackets 22 to each other by screwing and tightening two bolts 29 to the respective screw holes 22g through the respective bored holes 22f, thereby the flanges 11a of the strut 11 can be sandwiched and supported inside the respective L-shaped portions 22c of the both arm brackets 22. In brief, the strut 11 is sandwiched and supported between the arm brackets 22.

Thus, the central portion of the longitudinal beam 14 is coupled with the upper end 11d of the strut 11 via the beam bracket 21, while the arms 12, 13 are coupled with the body 11e of the strut 11 via the respective arm brackets 22.

The truss structure made up of the strut 11, two arms 12, 13 and the longitudinal beam 14 is provided for enhancing the strength of the structural object mount 5 according to the present embodiment.

Also, since the upper end 11d of the strut 11 is connected to the central portion of the longitudinal beam 14 and the opposite sides of the longitudinal beam 14 are supported by the respective arms 12, 13, the solar cell modules 2 on the longitudinal beam 14 can be stably supported. Moreover, as shown in FIG. 1, two rows of solar cell modules 2 are respectively allocated to opposite sides of the central portion of the longitudinal beam 14, therefore the loads of the solar cell modules 2 hardly act so as to cause the strut 11 to collapse, which further increases the stability of the structural object mount according to the present embodiment.

Furthermore, the height of the longitudinal beam 14 on each strut 11 can be adjusted. Even if there is a variation in heights of the struts 11, there must be no variation in height (vertical position) of each longitudinal beam 14 on the corresponding strut 11. For this reason, it is necessary to adjust and align the height of each longitudinal beam 14. Therefore, the two bolts 28 are loosened so that the beam bracket 21 can be moved in the direction of the elongated holes 11c of the web 11b of the strut 11. Also, the bolts 29 are loosened so that the arm brackets 22 and the arms 12, 13 can be moved along the strut 11. Thus, the longitudinal beam 14 can be moved in the vertical direction. After the height of the longitudinal beam 14 is appropriately adjusted, the bolts 28, 29 are tightened so as to secure the beam bracket 21, the arm brackets 22, the arms 12, 13 and the longitudinal beam 14. This makes it possible to adjust and align the height of each longitudinal beam 14.

Also, the position in the Y direction of each longitudinal beam 14 can be adjusted. The bolt 26, which tightens the central portion of the longitudinal beam 14 and the beam bracket 21, is loosened. The bolt 24, which tightens the area close to the front end of the longitudinal beam 14 and the upper portion of the arm coupling member 16, is loosened, and also the bolt 24, which tightens the area close to the rear end of the longitudinal beam 14 and the upper portion of the arm coupling member 16, is loosened. As a result, the longitudinal beam 14 can be moved relative to the bolts 24, 26 along the elongated holes 14e of the side plates 14a of the longitudinal beam 14. After the position in the Y direction of the longitudinal beam 14 is appropriately adjusted, the bolts 24, 26 are tightened so as to secure the longitudinal beam 14. This makes it possible to adjust and align the position in the Y direction of each longitudinal beam 14.

Next, a description will be given of a structure for connecting and securing the latitudinal beam 15 to the longitudinal beam 14.

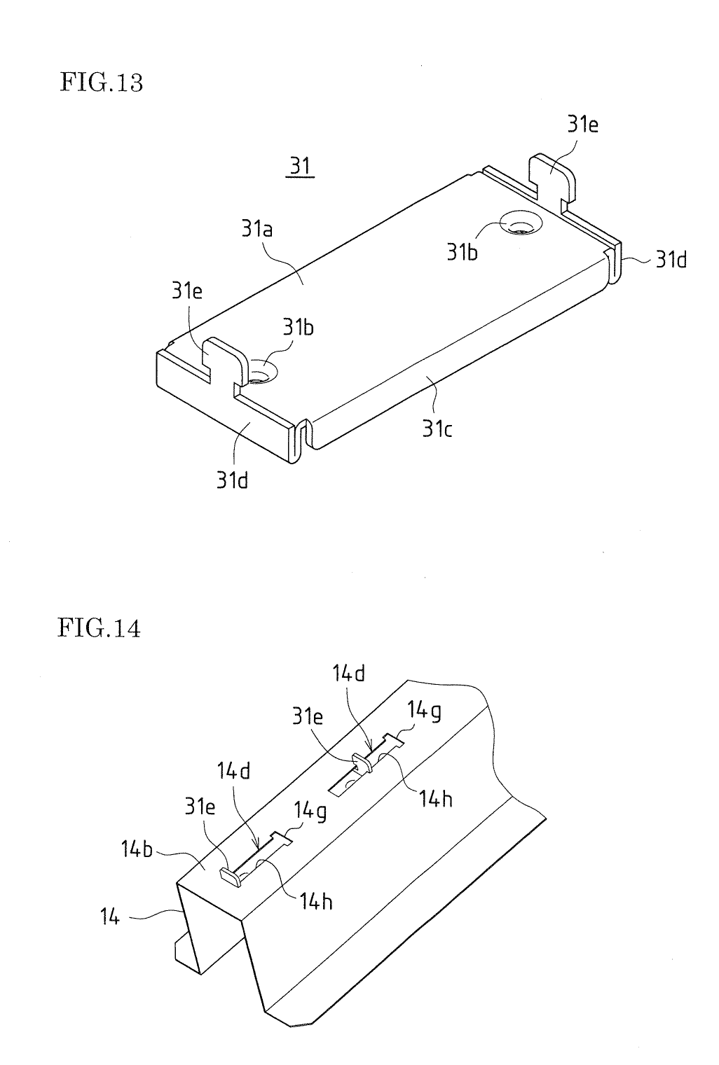

FIG. 13 is a perspective view showing an attachment bracket 31 used for connecting and securing the latitudinal beam 15 to the longitudinal beam 14. As shown in FIG. 13, the attachment bracket 31 includes a main plate 31a, a pair of side plates 31c bent on opposite sides of the main plate 31a, a pair of side plates 31d folded back twice respectively at the front end and the rear end of the main plate 31a, and a pair of T-shaped supporting pieces 31e each protruding from the center of the corresponding side plate 31d. Two screw holes 31b are formed in the main plate 31a.

As shown in FIG. 5, a pair of T-shaped holes 14d formed in respective vicinities of the opposite ends and at the central portion of the main plate 14b of the longitudinal beam 14. At each pair of the T-shaped holes 14d, the attachment bracket 31 is attached to the main plate 14b of the longitudinal beam 14. The attachment bracket 31 is disposed at each of three locations, that is, in the vicinities of the opposite ends and the central portion of the main plate 14b of the longitudinal beam 14.

As shown in FIG. 14, a head portion of each supporting piece 31e of the attachment bracket 31 is inserted into a corresponding slit 14g of the T-shaped hole 14d. The supporting piece 31e is moved to an engaging hole 14h of the T-shaped hole 14d and the head portion of the supporting piece 31e is hooked to the engaging hole 14h of the T-shaped hole 14d. Thus, the attachment bracket 31 is attached to the main plate 14b of the longitudinal beam 14.

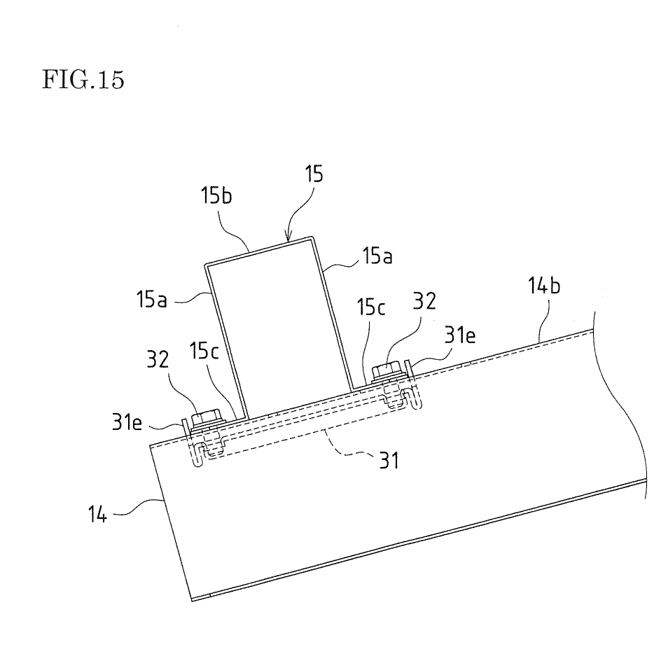

As shown in FIGS. 11 and 15, the latitudinal beam 15 is placed on the main plate 14b of the longitudinal beam 14 so as to be orthogonal to the longitudinal beam 14. The flanges 15c of the latitudinal beam 15 are arranged between the head portions of the supporting pieces 31e of the attachment bracket 31. Then, each of the elongated holes 15k of the flanges 15c of the latitudinal beam 15 is overlapped with the corresponding screw hole 31b of the attachment bracket 31 between which is interposed the corresponding T-shaped hole 14d of the main plate 14b of the longitudinal beam 14. Each bolt 32 is screwed and temporarily tightened to the corresponding screw hole 31b of the attachment bracket 31 through the corresponding elongated hole 15k of the flange 15c of the latitudinal beam 15 and the corresponding T-shaped hole 14d of the main plate 14b of the longitudinal beam 14.

In the temporarily tightened state, each bolt 32 can be moved along the corresponding elongated hole 15k of the flange 15c of the latitudinal beam 15. Therefore, the latitudinal beam 15 is moved along the elongated holes 15k (in the X direction in FIG. 1) such that the position in the X direction of the latitudinal beam 15 is adjusted.

The attachment bracket 31 can also be moved along the T-shaped holes 14d of the main plate 14b of the longitudinal beam 14 (in the longitudinal direction of the longitudinal beam 14). The latitudinal beam 15 can also be moved along with the attachment bracket 31. By the movement of the latitudinal beam 15 in the longitudinal direction of the longitudinal beam 14, the intervals among the three latitudinal beams 15 disposed on the longitudinal beam 14 are adjusted.

After the positions in the X direction of the three latitudinal beams 15 are adjusted and the intervals among the latitudinal beams 15 are adjusted, the bolts 32 of the attachment brackets 31 are tightened to secure the latitudinal beams 15 to the longitudinal beam 14.

Next, a description will be given of a first supporting bracket and a second supporting bracket for securing the solar cell modules 2 on the latitudinal beam 15.

As clearly seen from FIG. 1, the middle latitudinal beam 15 supports the ends of both the upper and lower solar cell modules 2. The upper or lower latitudinal beam 15 supports the end of the upper or lower solar cell module 2. Therefore, the support structure for the solar cell modules 2 in the middle latitudinal beam 15 differs from that in the upper or lower latitudinal beam 15, accordingly the first supporting bracket and the second supporting bracket are respectively used.

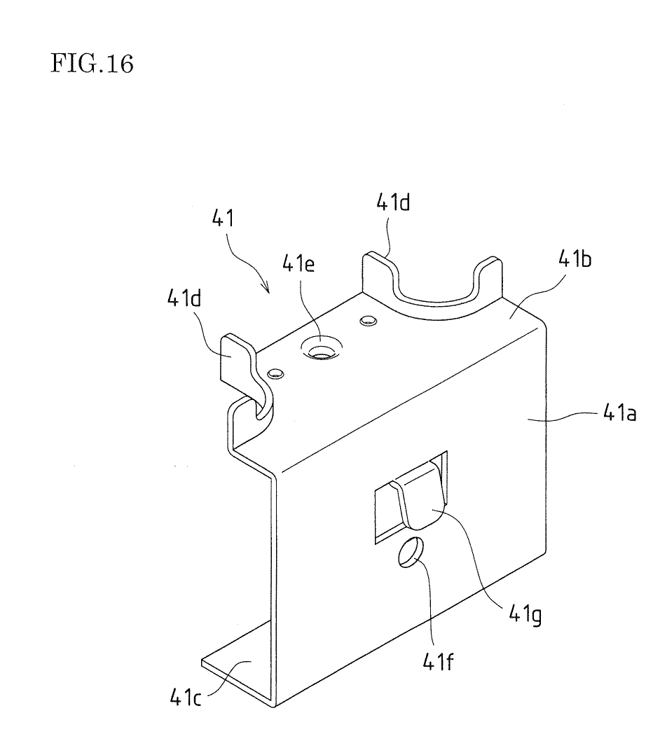

FIG. 16 is a perspective view showing the first supporting bracket for connecting and securing the solar cell modules 2 to the middle latitudinal beam 15. As shown in FIG. 16, the first supporting bracket 41 includes a side plate 41a, a main plate 41b bent at the upper edge of the side plate 41a and a bottom plate 41c bent at the lower edge of the side plate 41a. Protruding pieces 41d are formed so as to be bent at and raised from both corner portions of the main plate 41b. When viewed from above, each protruding piece 41d has a shape drawing a circular arc that curves to gouge out the corresponding corner portion of the main plate 41b. Also, a screw hole 41e is formed substantially in the center of the main plate 41b. Furthermore, a bored hole 41f is formed in the side plate 41a. A C-shaped cut is formed in the side plate 41a, so that the inside of the C-shaped cut is raised to form an engaging piece 41g. The height of the side plate 41a is substantially equal to the height of the side plates 15a of the latitudinal beam 15.

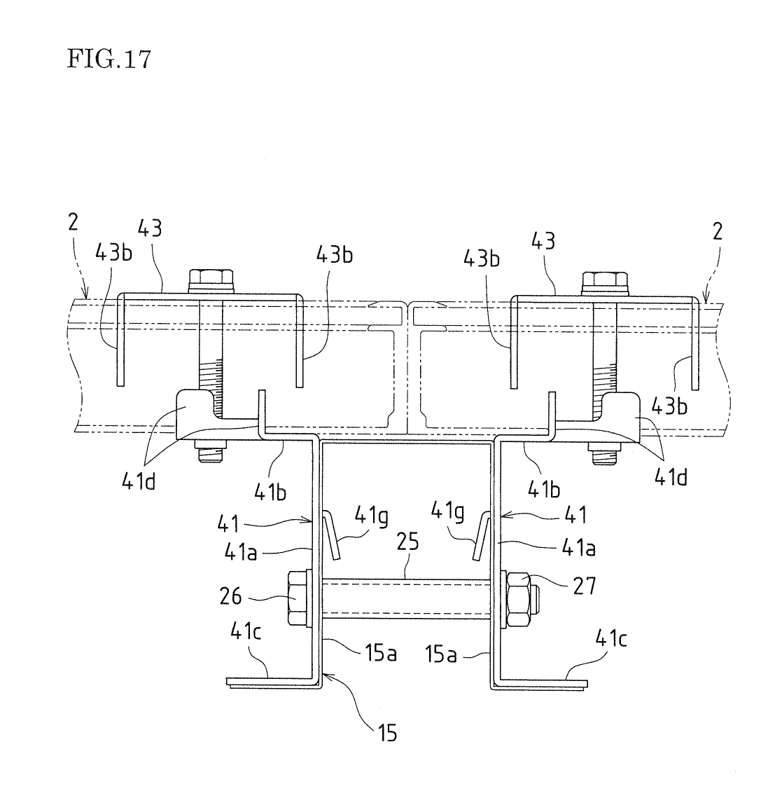

A pair of first supporting brackets 41 is disposed at each portion where the bored hole 15d and the slit 15g are formed in the side plates 15a of the middle latitudinal beam 15. As shown in FIG. 17, two first supporting brackets 41 are overlapped with the opposite sides of the latitudinal beam 15. The engaging piece 41g of the side plate 41a of each first supporting bracket 41 is engaged with the corresponding slit 15g of the side plate 15a of the latitudinal beam 15, so that each first supporting bracket 41 is temporary engaged. At this time, the main plate 41b of each first supporting bracket 41 protrudes outward from the latitudinal beam 15 and the protruding pieces 41d of each first supporting bracket 41 protrude upward from the main plate 15b of the latitudinal beam 15.

In this state, similarly to FIG. 12, a pipe 25 is inserted between the side plates 15a of the latitudinal beam 15. Positions of the pipe 25, the bored holes 15d of the side plates 15a of the latitudinal beam 15 and the bored holes 41f of the side plates 41a of the respective first supporting brackets 41 are aligned. A bolt 26 is passed through the pipe 25, the bored holes 15d of the side plates 15a of the latitudinal beam 15, the bored holes 41f of the side plates 41a of the respective first supporting brackets 41 and a washer. A nut 27 is screwed and fastened to one end of the bolt 26, thereby the pair of first supporting brackets 41 is secured to the middle latitudinal beam 15.

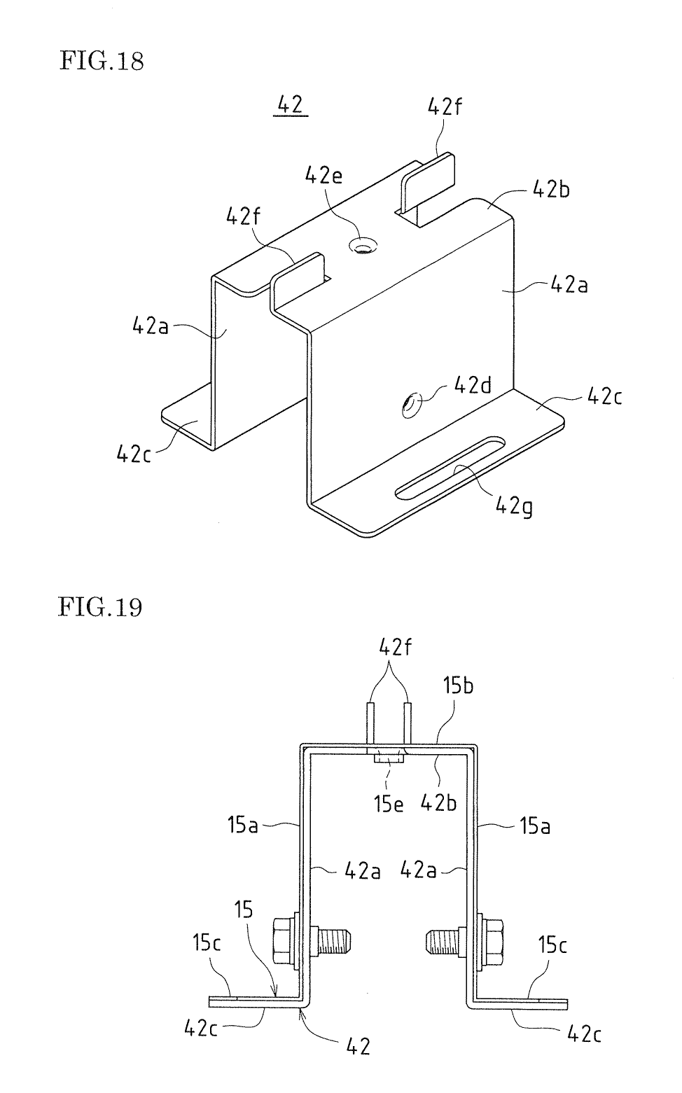

FIG. 18 is a perspective view showing the second supporting bracket for connecting and securing the solar cell modules 2 to the upper or lower latitudinal beam 15. As shown in FIG. 18, the second supporting bracket 42 has a substantially hat-shaped cross-section that is made up of a pair of side plates 42a that faces each other, a main plate 42b coupling opposite sides of the respective side plates 42a and flanges 42c each bent at an edge of the corresponding side plate 42a so as to protrude outward. The second supporting bracket 42 is set to have a size and shape being fitted inside of the latitudinal beam 15.

A L-shaped cut is formed inward from each of both ends of the main plate 42b of the second supporting bracket 42, so that the inside of the each L-shaped cut is raised to form a protruding piece 42f. Also in the second supporting bracket 42, a screw hole 42d is formed in each of the side plates 42a, a screw hole 42e is formed on the centerline of the main plate 42b and an elongated hole 42g is formed in each of the flanges 42c.

The second supporting bracket 42 configured in this manner is disposed at each portion where the pair of slits 15h and the open hole 15i are formed in the main plates 15b of the upper or lower latitudinal beam 15, so that the second supporting bracket 42 is fitted inside the latitudinal beam 15.

As shown in FIG. 19, when the second supporting bracket 42 is fitted inside the latitudinal beam 15, the protruding pieces 42f of the main plate 42b of the second supporting bracket 42 protrude upward from the pair of slits 15h of the main plate 15b of the latitudinal beam 15.

Also, the side plates 42a of the second supporting bracket 42 are overlapped with the respective side plates 15a of the latitudinal beam 15, the main plate 42b of the second supporting bracket 42 is overlapped with the main plate 15b of the latitudinal beam 15, and the flanges 42c of the second supporting bracket 42 are overlapped with the respective flanges 15c of the latitudinal beam 15.

In this state, two bolts are screwed and tightened to the respective screw holes 42d of the side plates 42a of the second supporting bracket 42 through the respective bored holes 15d of the side plates 15a of the latitudinal beam 15, so that the second supporting bracket 42 is secured. Therefore, in a portion in which the second supporting bracket 42 is secured, the main plates, the side plates and the flanges are all doubled, thus the above portion with the second supporting bracket 42 has increased strength.

The structural object mount 5 according to the present embodiment is provided on the assumption that almost all the members except for the struts 11, that is, the arms 12, 13, the longitudinal beams 14, the latitudinal beams 15, the arm coupling members 16, the beam brackets 21, the arm brackets 22, the first supporting brackets 41, the second supporting brackets 42 and the like, are assembled at the factory so as to be constructed as a flat structure, and that a plurality of such flat structures are stacked and transported from the factory to the installation site.

Here, as clearly seen from FIG. 1, the longitudinal beams 14 and the latitudinal beams 15 can be assembled in a ladder-like shape, that is, a flat structure that can be stacked.

Meanwhile, in FIGS. 10 and 11, the beam bracket 21 protrudes downward from the longitudinal beam 14. Also, the arms 12, 13 obliquely protrude downward the longitudinal beam 14 and the arm brackets 22 are spaced apart from the longitudinal beam 14. In this state, the beam bracket 21, the arms 12, 13 and the arm brackets 22 prevent the flat structure made up of the longitudinal beams 14 and the latitudinal beams 15 from being stacked.

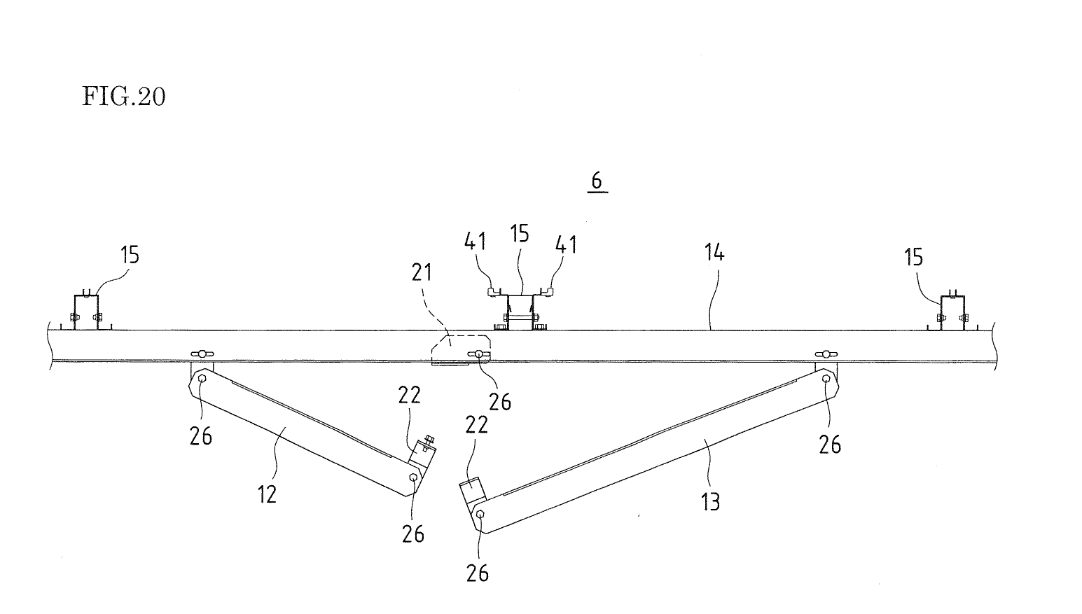

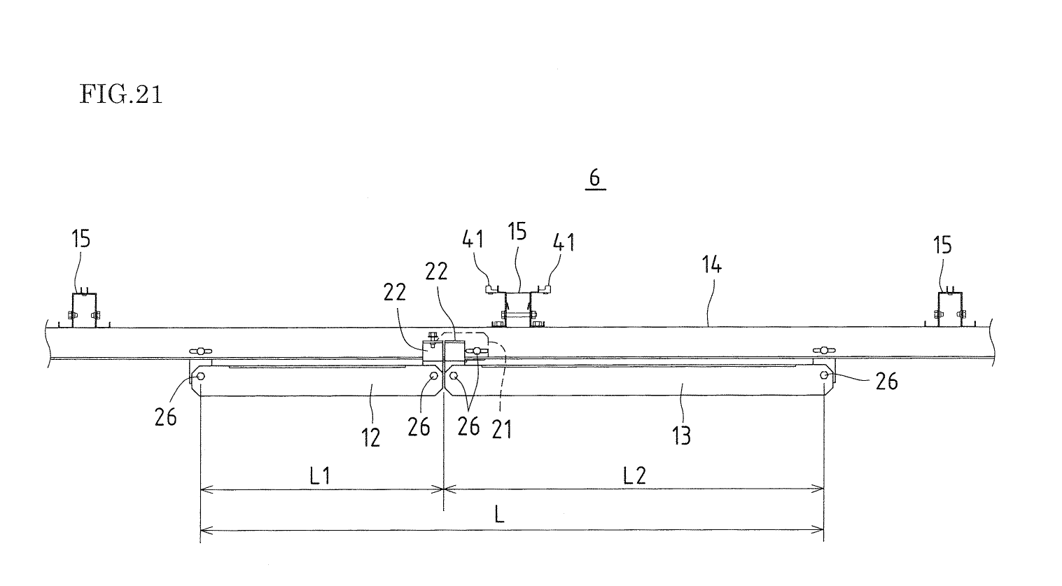

For this reason, in the structural object mount 5 according to the present embodiment, a mount member 6 is used. As shown in FIGS. 20 and 21, the mount member 6 can be constructed as a flat structure by folding the arms 12, 13, the beam bracket 21 and the arm brackets 22. In this mount member 6, the beam bracket 21 is rotated about the bolt 26 supporting the beam bracket 21 so as to be housed inside the side plates 21 of the longitudinal beam 14, as shown in FIG. 20. Also, as shown in FIG. 21, each arm 12, 13 is rotated about the corresponding bolt 26 supporting the arm 12 or 13 so as to be closed and aligned in parallel with the longitudinal beam 14. Furthermore, each arm bracket 22 is rotated about the corresponding bolt 26 supporting the arm bracket 22 so that the longitudinal beam 14 can be fitted inside the arm brackets 22.

More specifically, the side plates 21a of the beam bracket 21 are inserted inside the side plates 14a of the longitudinal beam 14 and the single bolt 26 pivotally supports the beam bracket 21. Thus, the beam bracket 21 is rotatable about the bolt 26. Also, it is possible to rotate the beam bracket 21 until the side plates 21a and the flanges 21c of the beam bracket 21 are overlapped with the side plates 14a and the flanges 14c of the longitudinal beam 14, respectively, so that the beam bracket 21 can be housed inside the side plates 21 of the longitudinal beam 14.

Also, the side plates 16a of the arm coupling member 16 are inserted inside the side plates 12a of the arm 12 and the single bolt 26 pivotally supports the arm 12. Thus, the arm 12 is rotatable about the bolt 26. Also, it is possible to rotate the arm 12 until the flanges 12c of the arm 12 are overlapped with the flanges 14c of the longitudinal beam 14, so that the arm 12 can be closed and aligned in parallel with the longitudinal beam 14. Likewise, the side plates 16a of the arm coupling member 16 are inserted inside the side plates 12a of the arm 13 and the single bolt 26 pivotally supports the arm 13. Thus, it is possible to rotate the arm 13 until the flanges 13c of the arm 13 are overlapped with the flanges 14c of the longitudinal beam 14, so that the arm 13 can be closed and aligned in parallel with the longitudinal beam 14.

Furthermore, as shown in FIG. 21, L, L1 and L2 are set so as to satisfy:

L>(L1+L2),

where the distance between the positions at which each arm 12, 13 is pivotally supported by the corresponding bolt 26 is expressed by L, the length from the position at which the arm 12 is pivotally supported by the bolt 26 to the end of the arm 12 is expressed by L1 and the length from the position at which the arm 13 is pivotally supported by the bolt 26 to the end of the arm 13 is expressed by L2. Thus, it is possible to close the arms 12, 13, between the respective bolts 26, in parallel with the longitudinal beam 14, while the arms 12, 13 are in line with each other.

Also, the side plates 22a of the arm bracket 22 are inserted inside the side plates 12a of the arm 12 or inside the side plates 13a of the arm 13. Each single bolt 26 pivotally supports the corresponding arm bracket 22. Thus, the arm brackets 22 can be rotated to face toward the longitudinal beam 14. The inside of the L-shaped portions 22c of the arm bracket 22 not only has a size and shape with which the flanges 11a of the strut 11 are fitted, but also has a size with which the flanges 14c of the longitudinal beam 14 are fitted. Therefore, by facing the arm bracket 22 toward the longitudinal beam 14, the longitudinal beam 14 can be fitted inside the L-shaped portions 22c of the arm bracket 22.

The state shown in FIG. 21 can be seen as the state in which the longitudinal beam 14 and the arms 12, 13 are overlapped so that the arms 12, 13 and the longitudinal beam 14 are aligned in the longitudinal direction, with the arms 12, 13 being in line with each other. The state shown in FIG. 20 can be seen as the state in which the mutually facing ends of the arms 12, 13 are spaced apart from the longitudinal beam 14 relative to the state shown in FIG. 21. Thus, the arm coupling members 16 are to couple the respective outer ends of the arms 12, 13 with the longitudinal beam 14 so that the arms 12, 13 are movable between the above-mentioned two states.

Note that, in the state shown in FIG. 21, the ends of arms 12, 13, which are provided with the respective arm brackets 22, are referred to as mutually facing ends, because they are facing each other. Also note that the other ends of the arms 12, 13, which are provided with the respective ends 22, are referred to as outer ends, because they are located outside.

Thus, the beam bracket 21 is housed inside the side plates 21a of the longitudinal beam 14. The arms 12, 13 are closed and aligned in parallel with the longitudinal beam 14 so that the arms 12, 13 are overlapped with the longitudinal beam 14. The longitudinal beam 14 is fitted inside the L-shaped portions 22c of each of the arm brackets 22. In such a state, the maximum thickness of the mount member 6 made up of the longitudinal beam 14, the arms 12, 13, the arm coupling members 16, the arm brackets 22, the beam bracket 21 and the like is equal to the sum of the height of the longitudinal beam 14 and the height of arm 12 or 13. Since the beam bracket 21, the arms 12, 13 and the arm brackets 22 are not bulky, the mount member 6 has a flat structure. Therefore, it is possible to stack and transport a plurality of such mount members 6.

Furthermore, in the state that the arms 12, 13 and the longitudinal beam 14 are overlapped by closing the arms 12, 13 so as to be aligned in parallel with the longitudinal beam 14, the flanges 12c, 13c of the respective arms 12, 13 are also overlapped with the flanges 14c of the longitudinal beam 14. Thus, even when a finger or the like is caught between the flange 12c or 13c and the flange 14c, it is prevented from being cut off. Also, as described below, dangers during installation of the structural object mount 5 can be reduced.

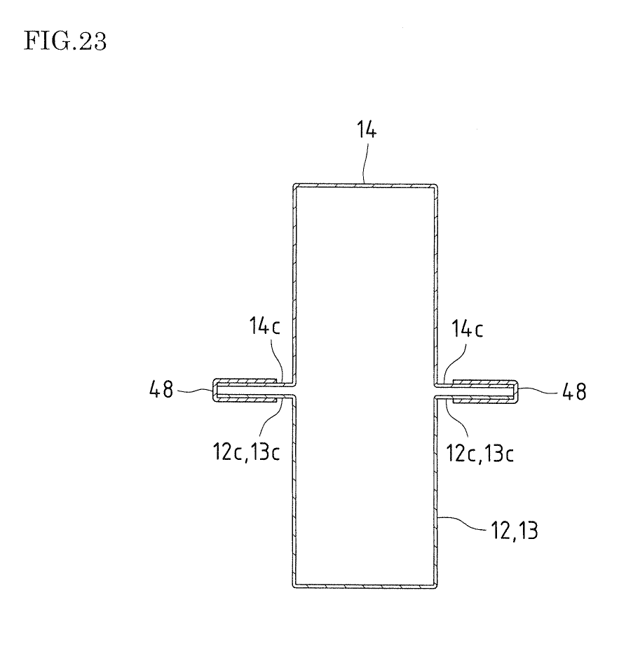

Furthermore, as shown in FIG. 23, the closed state of the arms 12, 13 can be kept using a clip 48 that sandwiches the flange 12c or 13c and the flange 14c overlapped with each other.

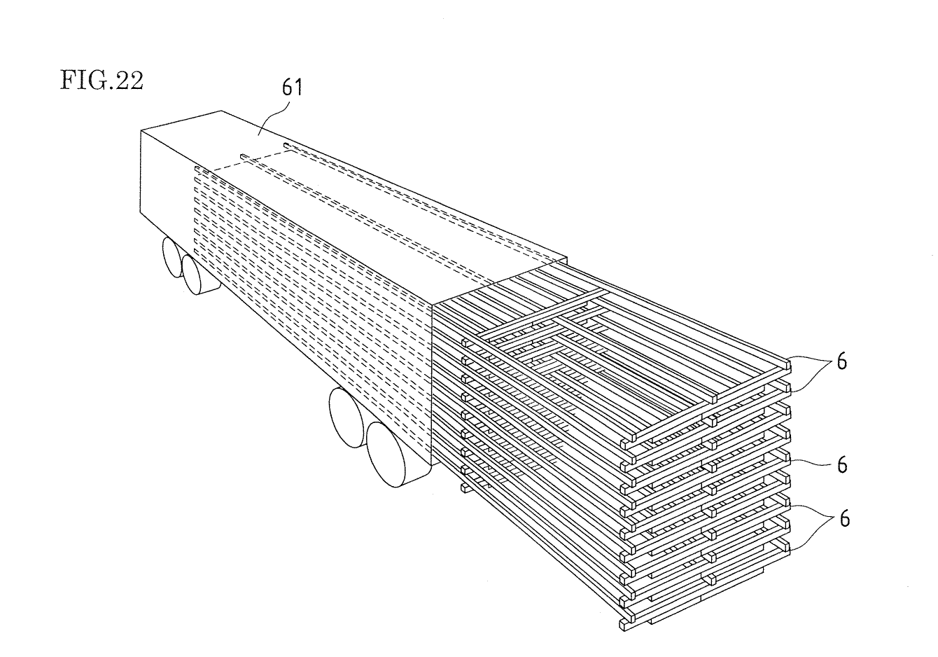

Here, the mount member 6 is made up of the arms 12, 13, the arm coupling members 16, the arm brackets 22 and the beam bracket 21. But the mount member 6 may include the latitudinal beams 15. FIG. 22 shows a state in which a plurality of such mount members 6 including the latitudinal beams 15 are placed onto a loading platform of a trailer 61 to be transported.

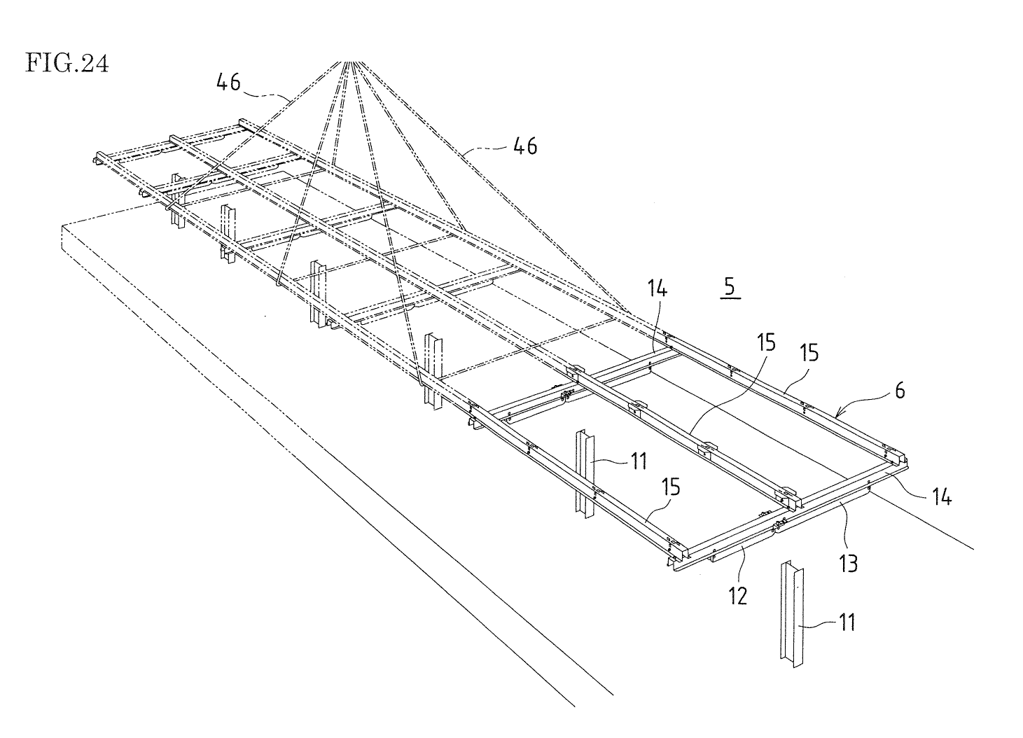

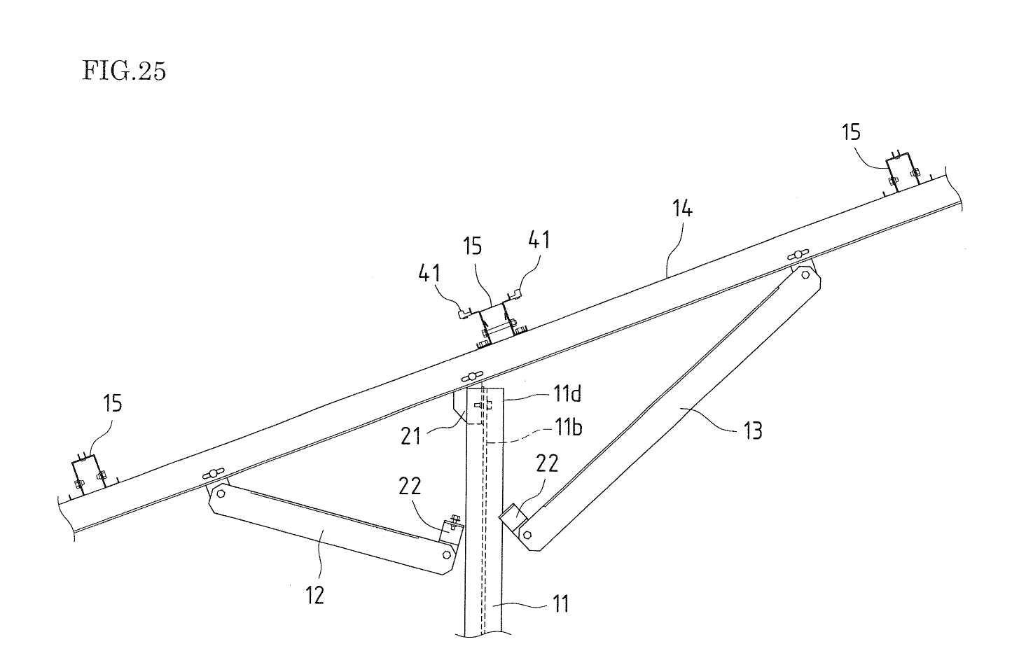

Next, a description will be given in an organized manner of an installation procedure of the solar photovoltaic system according to FIG. 1 with reference to FIGS. 24 and 25.

First, at the site where the structural object mounts 5 are to be installed, a plurality of struts 11 is erected on the ground at the same interval so as to be linearly arranged, as shown in FIG. 1. Each interval between the respective struts 11 is equal to the each arrangement interval between the respective longitudinal beams 14 of the structural object mount 5.

As shown in FIG. 22, a plurality of flat mount members 6 are stacked onto the loading platform of the trailer 61 and transported to the site.

At the site, as shown in FIG. 24, a plurality of wires 46 is hooked to the flat mount member 6 on the loading platform of the trailer 61. A crane hangs up and moves the flat mount member 6 by the wires 46 above the struts 11 so that the latitudinal beams 15 of the mount member 6 extend along the direction in which the struts 11 are arranged. Thus, the central portions of the longitudinal beams 14 of the mount member 6 are aligned with the respective struts 11. Also, the longitudinal beams 14 of the mount member 6 are inclined at an angle substantially the same as the angle indicated in FIG. 10.

For each longitudinal beam 14 of the mount member 6, the clips 48 as indicated in FIG. 23 are detached so that the arms 12, 13 are opened obliquely relative to the longitudinal beam 14, as shown in FIG. 25. While the mount member 6 is being lowered, the strut 11 is passed toward the longitudinal beam 14 through the arm brackets 22 disposed on the respective ends of the arms 12, 13. As shown in FIG. 10, the flanges 21c of the beam bracket 21 provided on the longitudinal beam 14 are overlapped with the web 11b of the strut 11, with the central portion of the longitudinal beam 14 being mounted on the upper end lid of the strut 11. Two bolts 28 are screwed and tightened to the respective screw holes 21e of the flanges 21c of the beam bracket 21 through the respective elongated holes 11c of the web lib. Thus, the central portion of the longitudinal beam 14 is coupled with the upper end lid of the strut 11 via the beam bracket 21.

Also, the arm brackets 22 of the arms 12, 13 face each other, with the strut 11 being interposed therebetween. The connecting plates 22d of one arm bracket 22 are overlapped with the connecting plates 22d of the other arm bracket 22. Each of two bolts 29 is screwed and tightened to the screw 22g of one connecting plate 22d through the bored hole 22f of the other connecting plate 22d. The strut 11 is sandwiched and supported between the arm brackets 22, thereby the structural object mount 5 is completed.

As stated above, when the distance between the positions at which each arm 12, 13 is pivotally supported is expressed by L, the length from the position at which the arm 12 is pivotally supported to the end of the arm 12 is expressed by L1 and the length from the position at which the arm 13 is pivotally supported to the end of the arm 13 is expressed by L2, L, L1 and L2 are set so as to satisfy the relationship L>(L1+L2). Therefore, it is not possible to construct the truss structure by only the longitudinal beam 14 and the arms 12, 13 due to the insufficient lengths of the arm 12, 13. However, since two arm brackets 22 are interposed between the respective ends of the arms 12, 13, and since the respective ends of the arms 12, 13 are spaced apart from each other, the each length of the arms 12, 13 is complemented so that the truss structure can be constructed.

Next, a description will be given of a procedure for mounting and securing the solar cell modules 2 on the structural object mount 5.

As stated above, the support structure for the solar cell modules 2 in the middle latitudinal beam 15 differs from that in the upper or lower latitudinal beam 15. Accordingly these support structures will be separately described.

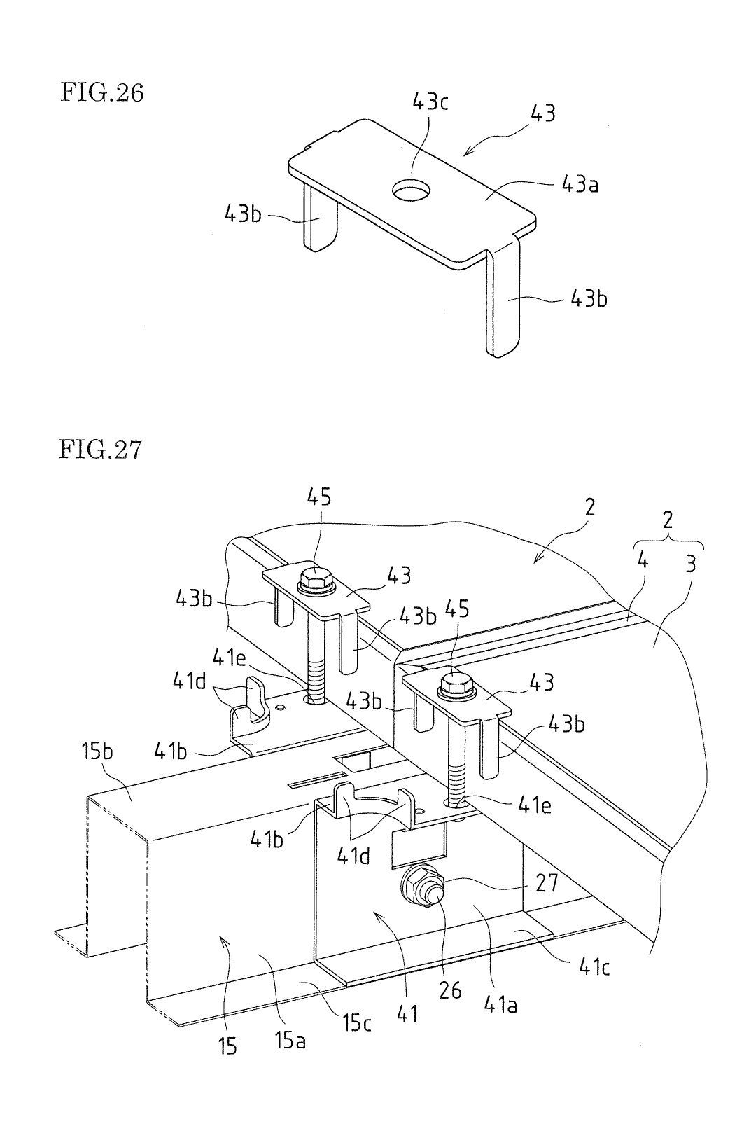

FIG. 26 is a perspective view showing a securing bracket disposed on a light-receiving surface side of the solar cell module 2. The securing bracket 43 includes protruding pieces 43b formed to be bent downward at a front end and a rear end of a pressing plate 43a and a bored hole 43c formed in a central portion of the pressing plate 43a.

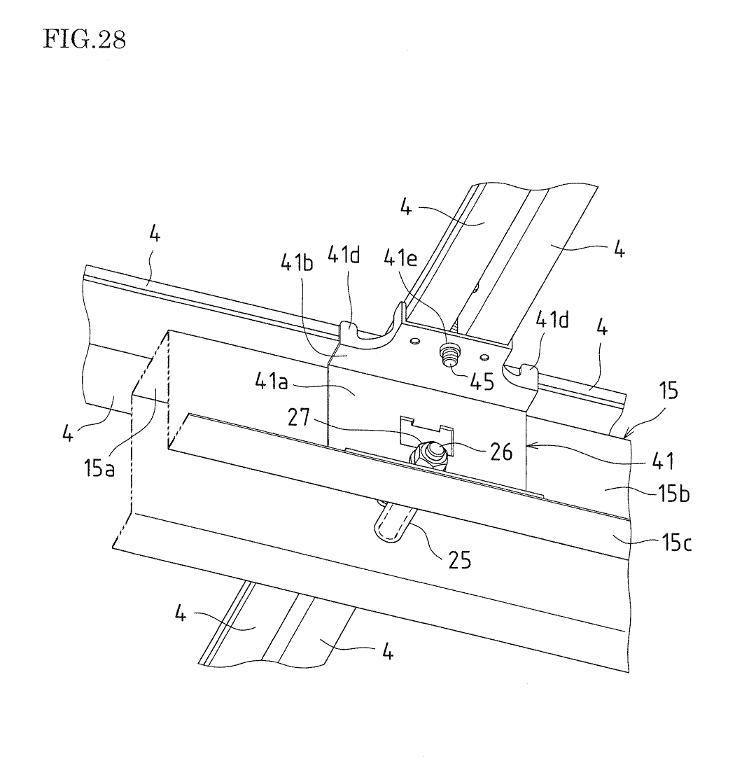

FIGS. 27 and 28 are perspective views showing a state in which the solar cell modules 2 are mounted on the middle latitudinal beam 15 using the first supporting brackets 41 and the securing brackets 43 as viewed respectively from above and from below. As shown in FIGS. 27 and 28, the frame members 4 of the respective solar cell modules 2 are inserted between the protruding pieces 41d of the first supporting brackets 41 so as to be placed on the main plate 15b of the latitudinal beam 15.

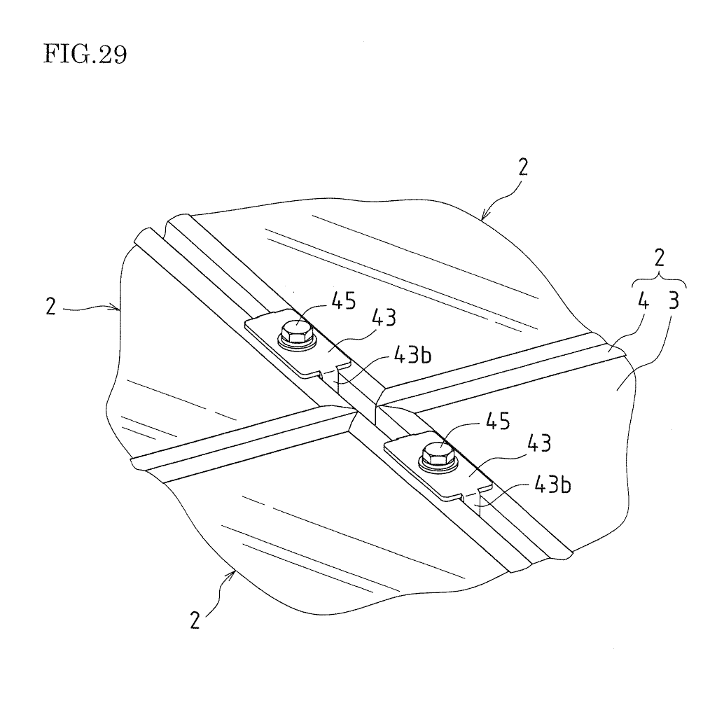

Then, as shown in FIG. 29, The protruding pieces 43b of the securing bracket 43 are inserted between the frame members 4 of the horizontally-adjacent solar cell modules 2 so that the frame members 4 of the adjacent solar cell modules 2 are spaced apart from each other at a fixed interval. A bolt 45 is screwed and tightened to the screw hole 41e of the main plate 41b of the first supporting bracket 41 through the bored hole 43c of the securing bracket 43 and an interspace between the frame members 4 of the respective solar cell modules 2. Thus, the frame members 4 of the respective solar cell modules 2 are sandwiched and secured between the securing bracket 43 and the main plate 15b of the latitudinal beam 15.

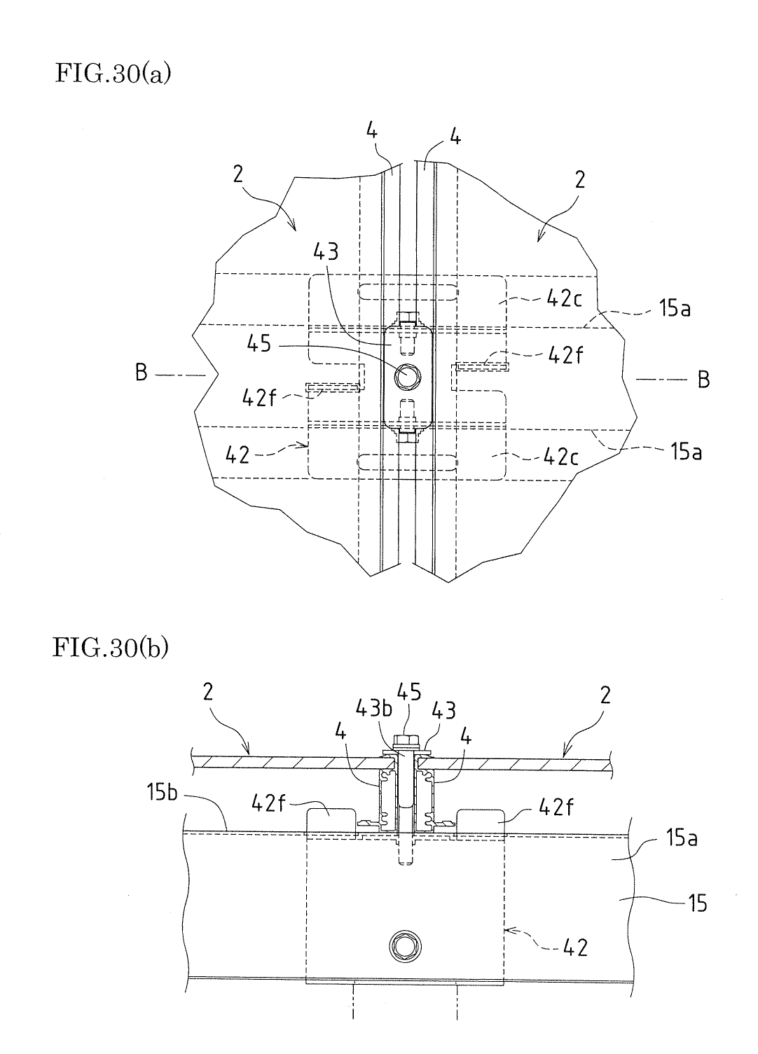

FIGS. 30(a) and 30(b) are respectively a plan view and a cross-sectional view showing a state in which two horizontally-adjacent solar cell modules 2 are mounted on the upper or lower latitudinal beam 15 using the second supporting bracket 42 and the securing bracket 43. As shown in FIGS. 30(a) and 30(b), the frame members 4 of the horizontally-adjacent solar cell modules 2 are inserted between the protruding pieces 42f of the second supporting bracket 42 so as to be placed on the main plate 15 of the latitudinal beam 15. Then, the protruding pieces 43b of the securing bracket 43 are inserted between the frame members 4 of the horizontally-adjacent solar cell modules 2 so that the frame members 4 of the respective solar cell modules 2 are spaced apart from each other at a fixed interval.

Successively, a bolt 45 is screwed and tightened to the screw hole 42e of the main plate 42 of the second supporting bracket 42 through the bored hole 43c of the securing bracket 43, an interspace between the frame members 4 of the respective solar cell modules 2 and the open hole 15i of the main plate 15b of the latitudinal beam 15. Thus, the frame members 4 of the respective solar cell modules 2 are sandwiched and secured between the securing bracket 43 and the main plate 15b of the latitudinal beam 15.

While a preferred embodiment of the present invention has been described, it should be appreciated that the present invention is not limited to the embodiment shown above.

For example, the outer end of the arm 12 (or 13) is pivotally supported by the downward protruding portion of the side plates 16a of the arm coupling member 16, thereby the arm 12 (or 13) can be overlapped with the longitudinal beam 14 so as to be closed and aligned in parallel with the longitudinal beam 14. In lieu of the above configuration, it may also be possible to secure the outer end of the arm 12 (or 13) to the downward protruding portion of the side plates 16a of the arm coupling member 16 and to cause the longitudinal beam 14 to pivotally support the upper portion of the side plates 16a of the arm coupling member 16. Thus, the arm 12 (or 13) is overlapped with the longitudinal beam 14 so as to be closed and aligned in parallel with the longitudinal beam 14. Also, it may be possible to extend the each end of the side plates 12a (or 13a) of the arm 12 (or 13) inside the side plates 14a of the longitudinal beam 14 so as to be pivotally supported by the side plates 14a of the longitudinal beam 14. Also, it may be possible to couple the arm 12 (or 13) with lower surfaces of the respective flanges 14c of the longitudinal beam 14 via a hinge.

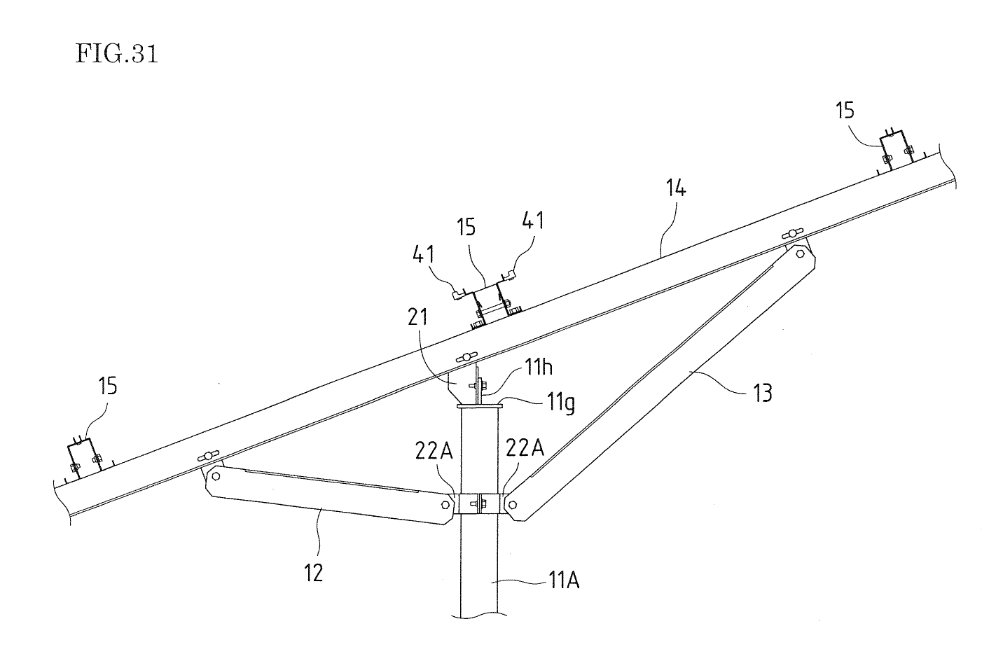

Also, it may be possible to apply a columnar strut 11A as shown in FIG. 31. In this case, a wall portion h is provided in a protruding manner on an upper end surface 11g of the strut 11A so that the beam bracket 21 is connected to the wall portion h. Also, appropriate arm brackets 22A are applied in order to sandwich the strut 11A. For example, an arc-shaped recess is formed inside each arm bracket 22A in order to sandwich the strut 11A.

The present invention may be embodied in a wide variety of forms other than those presented herein without departing from the spirit or essential characteristics thereof. The foregoing embodiments are therefore in all respects merely illustrative and are not to be construed in limiting fashion. The scope of the present invention being as indicated by the claims, it is not to be constrained in any way whatsoever by the body of the specification. All modifications and changes within the range of equivalents of the claims are, moreover, within the scope of the present invention.

Moreover, this application claims priority based on Patent Application No. 2010-175676 filed in Japan on 4 Aug. 2010. The content thereof is hereby incorporated in this application by reference. Furthermore, the entire contents of references cited in the present specification are herein specifically incorporated by reference.

### INDUSTRIAL APPLICABILITY

The present invention is suitable for use in a solar photovoltaic system.

### DESCRIPTION OF REFERENCE NUMERALS

2 Solar cell module
11 Strut
12, 13 Arm
14 Longitudinal beam
15 Latitudinal beam
16 Arm coupling member
21 Beam bracket
22 Arm bracket
25 Pipe
26, 45 Bolt
27 Nut
Attachment bracket
41 First supporting bracket
42 Second supporting bracket
   43 Securing bracket

1. A mount member supporting a structural object, comprising:
a beam;
two arms connected to a strut supporting the beam; and
a pair of arm coupling members,
wherein the pair of arm coupling members couples respective outer ends of the two arms with the beam such that the two arms are movable between a first state in which the beam and the two arms are overlapped and aligned in a longitudinal direction thereof with the two arms being in line with each other, and a second state in which mutually facing ends of the two arms are spaced apart from the beam relative to the first state.

2. The mount member according to claim 1, further comprising:
an arm bracket coupling each of the mutually facing ends of the arms with the strut supporting the beam;
wherein the arm bracket is rotatably provided at each of the mutually facing ends of the arms.

3. The mount member according to claim 2,
wherein the arm bracket is rotated toward the beam such that the beam can be fitted inside the arm bracket.

4. The mount member according to claim 1, further comprising:
a beam bracket coupling the beam with an upper end of the strut supporting the beam,
wherein the beam bracket is rotatably provided in an area between the pair of arm coupling members in the beam.

5. The mount member according to claim 4,
wherein the beam bracket is rotated so as to be housed inside the beam.

6. A structural object mount including the mount member according to any one of claim 1, comprising:
a strut supporting the beam;
wherein the mutually facing ends of the arms are connected to the strut in a state in which the mutually facing ends of the arms are spaced apart from the beam.

7. The structural object mount according to claim 6, further comprising:
a plurality of sets of the beam and the two arms;
wherein the beams are arranged in parallel as longitudinal beams, and
wherein a plurality of latitudinal beams is arranged in parallel on the longitudinal beams so as to be orthogonal to the longitudinal beams.

8. The structural object mount according to claim 7, wherein the structural object is a solar cell module.

9. A mount member supporting a structural object, comprising:
a plurality of longitudinal beams arranged in parallel;
two arms provided on each of the longitudinal beams, the two arms for connecting the longitudinal beam to a strut supporting the longitudinal beam;
a pair of arm coupling members; and
a plurality of latitudinal beams arranged in parallel on the longitudinal beams so as to be orthogonal to the longitudinal beams,
wherein the pair of arm coupling members is provided on each of the longitudinal beams, and
wherein the pair of arm coupling members couples respective outer ends of the two arms with the longitudinal beam such that the two arms are movable between a first state in which the longitudinal beam and the two arms are overlapped and aligned in a longitudinal direction thereof with the two arms being in line with each other, and a second state in which mutually facing ends of the two arms are spaced apart from the longitudinal beam relative to the first state.

10. A method for installing a structural object mount including the mount member according to any one of claim 1, comprising the steps of:
erecting the strut; and
hanging up and moving the longitudinal beam and the arms above an erected position of the strut, and lowering the longitudinal beam and the arms so as to connect the mutually facing ends of the arms to the strut in a state in which the mutually facing ends of the arms are spaced apart from the beam.

11. A method for installing the structural object mount including the mount member according to claim 9, comprising the steps of:
erecting and arranging the struts corresponding to the respective longitudinal beams; and
hanging up and moving a plurality of sets of the longitudinal beam and the arms coupled with the latitudinal beams above the erected positions of the struts, and lowering the plurality of sets of the longitudinal beam and the arms coupled with the latitudinal beams so as to connect each pair of the mutually facing ends of the respective arms to the corresponding strut in a state in which each pair of the mutually facing ends of the respective arms is spaced apart from the corresponding beam.

12. A solar photovoltaic system using the structural object mount according to claim 7,
wherein a plurality of solar cell modules is bridged and supported between the respective latitudinal beams.

13. A solar photovoltaic system using the structural object mount according to claim 8,
wherein a plurality of solar cell modules is bridged and supported between the respective latitudinal beams.
